(19) United States
(12) Patent Application Publication
(10) Pub. No.: US 2004/0192070 A1
(43) Pub. Date: Sep. 30, 2004

(54) Organic electroluminescent device and its production method

(76) Inventor: Tomomi Tateishi, Kanagawa-ken (JP)

Correspondence Address: BIRCH STEWART KOLASCH & BIRCH, PO BOX 747, FALLS CHURCH, VA, 22040-0747, US

(21) Appl. No.: 10/811,928

(22) Filed: Mar. 30, 2004

(30) Foreign Application Priority Data
Mar. 31, 2003 (JP) 2003-097329

(51) Int. Cl. H01L 21/31; H01L 21/469

(52) U.S. Cl. 438/780; 438/781

(57) ABSTRACT

An organic electroluminescent device is produced by a method using a transfer material having an organic layer formed on a support, which comprises the steps of superposing the transfer material on a first substrate having an electrode formed at least partially thereon such that the organic layer of the transfer material faces the electrode on the first substrate; applying heat and/or pressure thereto to form a laminate; and peeling the support from the laminate so that the organic layer is transferred onto the first substrate via the electrode, the first substrate having a maximum surface roughness Rmax of 0 to 50 according to JIS B 0601-1982, assuming that the organic layer has a thickness of 100.

### FIELD OF THE INVENTION

The present invention relates to a method for producing an organic electroluminescent device, which may be called an organic light-emitting device or an organic EL device, useful for full-color display devices, backlights of liquid crystal display devices, illumination surface light sources, light source arrays of printers, etc., and an organic electroluminescent device produced by such a method.

### BACKGROUND OF THE INVENTION

Much attention is paid to organic light-emitting devices such as organic electroluminescence (EL) devices usable for flat panel display devices. Specifically, the organic light-emitting devices are promising as inexpensive, solid-emission-type, large-emission-area, full-color display devices and writing light source arrays, and their development has been actively conducted. The organic light-emitting device generally comprises a couple of electrodes (a transparent electrode and a rear-surface electrode), and a light-emitting organic layer formed between the electrodes. When an electric field is applied to the electrodes, electrons are injected into the light-emitting layer from one electrode, while holes are injected thereinto from the other electrode. Electrons and holes are recombined in the light-emitting layer, and energy is emitted as light when an energy level is lowered from a conduction band to a valence band.

As a method for forming an organic layer of the organic EL device, for instance, WO 00/41893 discloses a method for thermally transferring an organic layer and a photo-thermal conversion layer onto a substrate by a laser beam by using a donor sheet having an organic layer and a photo-conversion layer.

However, such a thermal transfer method is disadvantageous in that a gas often penetrates into an interface between the organic layer and the substrate. The light-emitting efficiency, durability and uniformity of the organic EL device may vary depending on the conditions of the interface of the organic layer, whereby the organic EL device shows poor light-emitting properties when a gas penetrates into the interface.

In the case of transferring an organic layer from a donor onto a substrate by thermal writing in a predetermined pattern using a thermal head or a laser common in printing technologies, a temperature distribution generated around an organic, thin-film pattern by thermal diffusion blurs its outline, failing to cut the organic, thin-film pattern from the donor accurately. Thus, organic light-emitting devices produced by this method are uneven in light emission and likely to suffer from poor durability, because of insufficient electric connection and the breakage of the organic layer. Further, yield is likely to be low because of low-accuracy positioning of the substrate and the thermal head or laser beam.

### OBJECTS OF THE INVENTION

Accordingly, an object of the present invention is to provide a method for easily forming an organic layer on a substrate, thereby producing a uniform organic electroluminescent device with a good lamination interface, particularly a method for producing an organic electroluminescent device excellent in light-emitting efficiency and durability by forming a uniform organic layer on a substrate.

Another object of the present invention is to provide an organic electroluminescent device obtained by such a method.

### SUMMARY OF THE INVENTION

As a result of intense research in view of the above objects, the inventor has found that an organic layer can be easily formed on a substrate to produce a uniform organic electroluminescent device with a good lamination interface by using a substrate having a maximum surface roughness Rmax of 0 to 50 according to JIS B 0601-1982, assuming that the organic layer has a thickness of 100.

Thus, the first method of the present invention for producing an organic electroluminescent device using a transfer material comprising at least one organic layer formed on a support comprises superposing the transfer material on a first substrate having an electrode formed at least partially thereon such that the organic layer of the transfer material faces the electrode on the first substrate; applying heat and/or pressure thereto to form a laminate; and peeling the support from the laminate so that the organic layer is transferred onto the first substrate via the electrode; wherein the first substrate has a maximum surface roughness Rmax of 0 to 50 according to JIS B 0601-1982, assuming that the thickness of the organic layer is 100.

The second method of the present invention for producing an organic electroluminescent device using a transfer material comprising at least one organic layer formed on a plate having a pattern comprises superposing the transfer material on a first substrate having an electrode formed at least partially thereon such that the organic layer of the transfer material faces the electrode on the first substrate; applying heat and/or pressure thereto to form a laminate; and peeling the plate form the laminate so that the organic layer is transferred onto the first substrate via the electrode; wherein the first substrate has a maximum surface roughness Rmax of 0 to 50 according to JIS B 0601-1982, assuming that the thickness of the organic layer is 100.

In the first and second methods, after the organic layer is transferred onto the first substrate via the electrode, a second substrate having an electrode formed at least partially thereon is preferably superposed on the first substrate such that the electrode on the second substrate is in contact with the organic layer transferred onto the first substrate. The second substrate preferably has a maximum surface roughness Rmax of 0 to 50 according to JIS B 0601-1982, assuming that the thickness of the organic layer is 100. At least one of the first and second substrates preferably has a linear thermal expansion coefficient of 20 ppm/° C. or less. A flat layer may be formed on at least one of the first and second substrates. The flat layer is preferably made of at least one material selected form the group consisting of ultraviolet-curing organic compounds, electron beam-curing organic compounds, thermosetting organic compounds, inorganic oxides and inorganic nitrides.

In the first and second methods, the transfer material preferably comprises a light-emitting organic layer. Plural organic layers may be transferred onto the first substrate via the electrode by using a plurality of transfer materials comprising the same or different organic layers, or by using one transfer material comprising a plurality of the same or different organic layers.

At least one of the electrodes formed on the first and second substrates is preferably transparent, and at least one of the first and second substrates is preferably transparent. Another organic layer may be formed on one or both of the first and second substrates by a coating method, etc. in addition to the organic layer to be transferred from the transfer material.

The organic electroluminescent device obtained by the first or second method of the present invention is excellent in light-emitting efficiency and durability.

### BRIEF DESCRIPTION OF THE DRAWING

FIG. 1 is a graph showing a maximum surface roughness Rmax according to JIS B 0601-1982.

### DETAILED DESCRIPTION OF THE PREFERRED EMBODIMENTS

The present invention is described in detail below.

[1] First and Second Substrates

(1) First Substrate

The first substrate used in the present invention acts as a support, to which an organic layer is transferred from a transfer material by a peeling transfer method. The first substrate, onto which the organic layer is transferred, has a maximum surface roughness Rmax of 0 to 50 according to JIS B 0601-1982, assuming that the thickness of the organic layer of the transfer material is 100. When the maximum surface roughness Rmax is more than 50, the organic layer formed on the first substrate by the peeling transfer method is poor in layer properties such as adhesion to the first substrate, and the resultant organic electroluminescent device suffers from unevenness in properties such as light-emitting properties due to short- circuiting, detachment, etc. The maximum surface roughness Rmax is preferably 0.0001 to 25, more preferably 0.01 to 25, particularly 0.01 to 10.

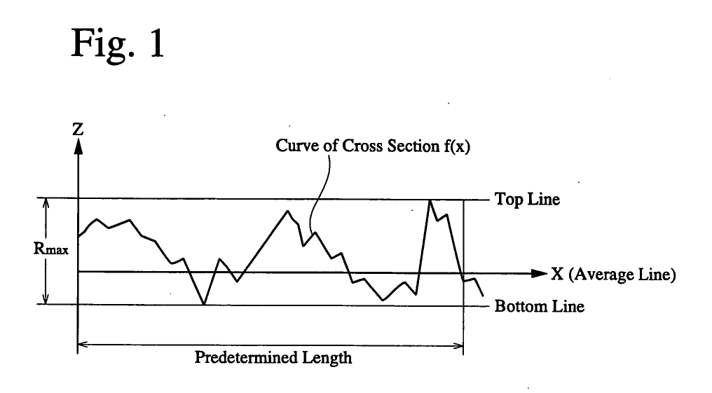

As shown in FIG. 1, the maximum surface roughness Rmax according to JIS B 0601-1982 is represented by a difference in a vertical direction (Z-axis direction) between a top line passing through the highest point and a bottom line passing through the lowest point, parallel to a line X representing an average height, in a curve representing a section of the substrate within a predetermined length. The maximum surface roughness Rmax may be measured by an interatomic-force microscope, a confocal microscope, a stylus method, an optical microscopic interference method, a multi-interference method, an optical cutting method, etc. The maximum surface roughness Rmax is preferably measured by an interatomic-force microscope or a confocal microscope.

The first substrate preferably has a linear thermal expansion coefficient of 20 ppm/° C. or less. The linear thermal expansion coefficient may be measured by a method of detecting the change of the length of a sample while heating the sample at a constant rate, such as a TMA method. When the linear thermal expansion coefficient of the first substrate is more than 20 ppm/° C., the electrode or the organic layer is likely to be cracked or peel off by cooling or heating after the transferring step, resulting in poor adhesion.

The first substrate may be composed of any material as long as it can form a support with a maximum surface roughness Rmax of 0 to 50 according to JIS B 0601-1982. Specific examples of materials for the first substrate include inorganic materials such as yttrium-stabilized zirconia (YSZ) and glass; metals such as aluminum, copper, stainless steel, gold, and silver; plastics such as polyimides, liquid crystal polymers, fluororesins such as tetrafluoroethylene resins (PTFE) and trifluorochloroethylene resins (PCTFE), polyesters such as polyethylene terephthalate and polyethylene naphthalate (PEN), polycarbonates, polyether sulfones (PES), and rigid polyvinyl chlorides; etc. The first substrate may be composed of one material or a laminate of plural materials. The first substrate is preferably an aluminum sheet, a copper sheet, a polyimide sheet, a rigid polyvinyl chloride sheet, or a laminate thereof, from the viewpoint of workability and cost. The thickness of the first substrate is generally 5 μm to 3 mm, preferably 25 μto 1 mm, more preferably 50 μm to 0.5 mm. The first substrate may be transparent or opaque. In the case of light emission from the organic electroluminescent device through the first substrate, it is preferred that the first substrate is substantially colorless transparent to reduce the scattering and attenuation of light. The term “substantially colorless transparent” used herein means that the light transmittance is 10% or more. The light transmittance of the first substrate is preferably 50% or more, particularly 70% or more.

A flat layer may be formed on the first substrate, and the organic layer may be transferred onto the flat layer. The maximum surface roughness Rmax (JIS B 0601-1982) of the first substrate, to which the organic layer is transferred, can be controlled by forming the flat layer. Materials for the flat layer are not particularly limited as long as they do not reduce the light-emitting properties of the organic electroluminescent device. The flat layer preferably comprises at least one material selected form the group consisting of ultraviolet-curing organic compounds, electron beam-curing organic compounds, thermosetting organic compounds, inorganic oxides and inorganic nitrides.

Monomers as the ultraviolet-curing, electron beam-curing, or thermosetting organic compounds for forming the flat layer are not particularly restricted. The monomers are addition-polymerized or ring-opening-polymerized into resins by ultraviolet rays, electron beams, or heat. Examples of addition-polymerizable monomers include compounds with an ethylenic unsaturated bond. Examples of ring-opening-polymerizable monomers include compounds with an epoxy group.

The compounds with an ethylenic unsaturated bond has an unsaturated moiety containing one or more carbon-carbon unsaturated bonds. Examples of the compounds include acrylic acid and salts thereof, acrylic esters, acrylamide compounds, methacrylic acid and salts thereof, methacrylic esters, methacrylamide compounds, urethane acrylates, urethane methacrylates, maleic anhydride, maleic esters, itaconic esters, styrene compounds, vinyl ethers, vinyl esters, N-vinyl heterocyclic compounds, allyl ethers, allyl esters, derivatives thereof, etc. The compounds have an acryloyl group, a methacryloyl group, an ethacryloyl group, an acrylamide group, an allyl group, a vinyl ether group, a vinyl thioether group, etc. The compounds may be used alone or in combination. The compound with an ethylenic unsaturated bond may be a monomer having an epoxy ring such as glycidyl acrylate, a polymerizable oligomer, or a polymerizable polymer. Typical specific examples of the compounds with an ethylenic unsaturated bond are explained below without intention of restricting the scope of the present invention.

The (meth)acrylic esters include polyester acrylates and polyester methacrylates. Examples of commercially available polyester acrylates and polyester methacrylates include Aronix M-5300, Aronix M-5400, Aronix M-5500, Aronix M-5600, Aronix M-5700, Aronix M-6100, Aronix M-6200, Aronix M-6300, Aronix M-6500, Aronix M-7100, Aronix M-8030, Aronix M-8060, and Aronix M-8100 (trade names, Toagosei Chemical Industry Co., Ltd.); Biscoat 700 and Biscoat 3700 (trade names, Osaka Organic Chemical Industry Ltd.); Kayarad HX-220 and Kayarad HX-620 (trade names, Nippon Kayaku Co., Ltd.); etc.

The compounds with an ethylenic unsaturated bond and an epoxy ring include epoxy acrylates and epoxy methacrylates. Examples of commercially available epoxy acrylates and epoxy methacrylates include NK ester EA-800 and NK ester EPM-800 (trade names, Shin-Nakamura Chemical Co., Ltd.); Biscoat 600 and Biscoat 540 (trade names, Osaka Organic Chemical Industry Ltd.); Photomer 3016 and Photomer 3082 (trade names, San Nopco Ltd.); etc.

Examples of commercially available urethane acrylates and urethane methacrylates include Aronix M- 1100, Aronix M- 1200, Aronix M-1210, Aronix M-1250, Aronix M-1260, Aronix M-1300, and Aronix M-1310 (trade names, Toagosei Chemical Industry Co., Ltd.); Biscoat 812, Biscoat 823, and Biscoat 832 (trade names, Osaka Organic Chemical Industry Ltd.; NK Ester U-4HA, NK Ester U-108A, NK Ester U-122A, NK Ester U-200AX, NK Ester U-340AX, NK Ester U-1084A, NK Ester U-4HA, NK Ester U-6HA, NK Ester U-324A, NK Ester U-A-100, NK Ester U-401A, NK Ester U-1301A, NK Ester U-601BA, NK Ester U-100BA, NK Ester U-423A, NK Ester U-412TXA, NK Ester U-423TXA, and NK Ester U-0108B (trade names, Shin-Nakamura Chemical Co., Ltd.); etc.

Examples of monofunctional acrylates and monofunctional methacrylates include methyl acrylate, ethyl acrylate, butyl acrylate, methyl methacrylate, butyl methacrylate, 2-ethylhexyl acrylate, ethoxyethyl acrylate, 2-hydroxyethyl acrylate, 2-hydroxyethyl methacrylate, 2-hydroxypropyl acrylate, furfuryl acrylate, tetrahydrofurfuryl acrylate, phenoxyethyl acrylate, cyclohexyl acrylate, cyclohexyl methacrylate, benzyl acrylate, tricyclodecanyloxy acrylate, nonylphenyloxyethyl acrylate, 1,3-dioxolane acrylate, glycidyl methacrylate, N,N-dimethylaminoethyl acrylate, N,N-dimethylaminoethyl methacrylate, N,N-diethylaminoethyl methacrylate, butoxyethyl acrylate, etc. Further examples of the mono functional acrylates and the monofunctional methacrylates include ethylene oxide-modified phenoxylated phosphoric acrylate; ethylene oxide-modified butoxylated phosphoric acrylate; Aronix M-101, Aronix M-102, Aronix M-111, Aronix M-113, Aronix M-114, Aronix M-117, Aronix M-120, Aronix M-152, and Aronix M-154 (trade names, Toagosei Chemical Industry Co., Ltd.); MK Ester M-20G, MK Ester M-40G, MK Ester M-90G, MK Ester M-230GCB-1, MK Ester SA, MK Ester S, Topolene-M, MK Ester AMP- 1 8G, MK Ester AMP-20G, MK Ester AMP-60G, MK Ester AM-90G, MK Ester A-SA, and MK Ester LA (trade names, Shin-Nakamura Chemical Co., Ltd.); etc.

Examples of polyfunctional acrylates, polyfunctional methacrylates, and polyfunctional oligomers include 1,6-hexanediol diacrylate, 1,6-hexanediol dimethacrylate, neopentyl glycol diacrylate, butanediol dimethacrylate, neopentyl glycol dimethacrylate, trimethylolpropane triacrylate, trimethylolpropane trimethacrylate, diethylene glycol diacrylate, polyethylene glycol diacrylate, polyethylene glycol dimethacrylate, polypropylene glycol diacrylate, butanediol diacrylate, tricyclodecanedimethylol diacrylate, polypropylene glycol dimethacrylate, pentaerythritol diacrylate, dipentaerythritol hexaacrylate, dipentaerythritol hexaacrylate, dipentaerythritol pentaacrylate, isocyanuric acid diacrylate, pentaerythritol triacrylate, pentaerythritol trimethacrylate, pentaerythritol tetramethacrylate, isocyanuric acid triacrylate, trimethylolpropane triacrylate, trimethylolpropane trimethacrylate, pentaerythritol tetraacrylate, ethylene oxide-modified pentaerythritol tetraacrylate, propylene oxide-modified pentaerythritol tetraacrylate, propylene oxide-modified dipentaerythritol polyacrylate, ethylene oxide-modified dipentaerythritol polyacrylate, a dimethacrylate derivative of polyoxyalkylenated bisphenol A, a diacrylate derivative of polyoxyethylenated bisphenol A, 2-(2-hydroxy-1,1-dimethylethyl)-5-hydroxymethyl-5-ethyl-1,3-dioxane diacrylate, 2-(2-hydroxy-1,1-dimethylethyl)-5,5-dihydroxymethyl-1,3-dioxane triacrylate, a triacrylate derivative of a trimethylolpropane-propylene oxide-adduct, a hexaacrylate derivative of a dipentaerythritol-caprolactone-adduct, polyacrylate derivatives of hydroxy polyethers, etc.

Examples of commercially available polyfunctional acrylates, polyfunctional methacrylates, and polyfunctional oligomers include Aronix M-210, Aronix M-215, Aronix M-220, Aronix M-230, Aronix M-233, Aronix M-240, Aronix M-245, Aronix M-305, Aronix M-309, Aronix M-310, Aronix M-315, Aronix M-320, Aronix M-325, Aronix M-330, Aronix M-400, Aronix TO-458, Aronix TO-747, Aronix TO-755, Aronix THIC, and Aronix TA2 (trade names, Toagosei Chemical Industry Co., Ltd.); Kayarad TC-110S, Kayarad TC-120S, Kayarad HDDA, Kayarad NPGDA, Kayarad TPGDA, Kayarad PEG400DA, Kayarad MANDA, Kayarad HX-220, Kayarad HX-620, Kayarad R-551, Kayarad R-712, Kayarad R-604, Kayarad R-167, Kayarad TPA-320, Kayarad TPA-330, Kayarad PET-30, Kayarad D-310, Kayarad D-330, Kayarad DPHA, Kayarad DPCA-20, Kayarad DPCA-30, Kayarad DPCA-60, and Kayarad DPCA-120 (trade names, Nippon Kayaku Co., Ltd.); NK Ester 1G, NK Ester 2G, NK Ester 3G, NK Ester 4G, NK Ester 5G, NK Ester 14G, NK Ester 23G, NK Ester BG, NK Ester HD, NK Ester NPG, NK Ester APG-400, NK Ester APG-700, NK Ester A-BPE-4, NK Ester 701A, NK Ester TMPT, NK Ester A-TMPT, NK Ester A-TMM-3, NK Ester A-TMM-3L, NK Ester A-TMMT, NK Ester 9PG, NK Ester 701, NK Ester BPE-100, NK Ester BPE-200, NK Ester BPE-500, NK Ester BPE-1300, NK Ester A-200, NK Ester A-400, NK Ester A-600, NK Ester A-HD, NK Ester A-NPG, NK Ester APG-200, NK Ester A-BPE-10, NK Ester 701-A, and NK Ester A-BPP-3 (trade names, Shin-Nakamura Chemical Co., Ltd.); etc.

Further examples of the compounds with an ethylenic unsaturated bond include acrylonitrile, methacrylonitrile, acrylamide, vinyl acetate, vinyl propionate, vinylpyrrolidone, unsaturated esters of polyols such as ethylene diacrylate, diethylene glycol diacrylate, glycerol triacrylate, trimethylolpropane triacrylate, pentaerythritol tetraacrylate, and acryloylmorpholine, etc. The compounds may have two or more unsaturated bonds.

Specific examples of the ring-opening-polymerizable compounds with an epoxy group include an epoxy-containing glycidyl ethers, and Epolight M-1230, Epolight 40E, Epolight 200E, Epolight 400E, Epolight 70P, Epolight 200P, Epolight 400P, Epolight l50ONP, Epolight 1600, Epolight 80MF, Epolight 100MF, Epolight 4000, Epolight 3002, and Epolight FR-1500 (trade names, Kyoeisha Chemical Co., Ltd.), etc.

The monomer is preferably a polyfunctional compound, a polymerizable oligomer, or a polymerizable polymer, and examples thereof include prepolymers of polyesters, polyurethanes, epoxy resins, polyethers, polycarbonates, etc., which have an acrylate group in the chain end or the side chain. Particularly preferable among them are polyesters having an acrylate group such as pentaerythritol acrylate, and polyurethanes having an acrylate group such as NK Ester U-108A and NK Ester U-1001BA available from Shin-Nakamura Chemical Co., Ltd.

Among them, preferable radical polymerizable monomers are urethane acrylate monomers, acryl monomers, and methacryl monomers, and preferable cationic polymerizable monomers are epoxy-containing glycidyl ethers.

A reaction initiator, a sensitizer, a crosslinking agent, a hardening agent, a polymerization promotor, etc. may be added to the monomers if necessary. Examples of photoreaction initiators and photopolymerization initiators include benzophenone compounds, acetophenone compounds such as dichloroacetophenone and trichloroacetophenone, benzoin compounds, thioxanthone compounds, Michler's Ketone, benzyl compounds, benzoin alkyl ethers, benzyl dimethyl ketal, tetramethylthiuram monosulfide, azo compounds, etc. The initiators are described in detail in Ultraviolet Ray Hardening System, pages 63 to 147 (1989, General Technical Center), etc. Preferable photoreaction initiators are benzophenone compounds and acetophenone compounds. Specific examples of the initiators include Irgacure 184, Irgacure 651, and Irgacure 1174 (trade names, Ciba-Geigy Japan Ltd.), etc.

Cationic polymerization initiators may be used for ring-opening polymerization. Examples of the cationic polymerization initiators include aromatic onium salts, sulfonium salts of elements of Group VIa of the Periodic Table of Elements, etc. Specific examples of the aromatic onium salts include salts of elements of Group Va of the Periodic Table of Elements such as triphenylphenacylphosphonium hexafluorophosphate; salts of elements of Group VIa of the Periodic Table of Elements such as triphenylsulfonium tetrafluoroborate, triphenylphosphonium hexafluorophosphate, tris(4-thiomethoxyphenyl)sulfonium hexafluorophosphate, and triphenylsulfonium hexafluoroantimonate; and salts of elements of Group VIIa of the Periodic Table of Elements such as diphenyliodonium chloride. In the case of using the aromatic onium salt as the cationic polymerization initiator, an epoxy compound is preferably used as the monomer. This is described in detail in U.S. Pat. Nos. 4,058,401, 4,069,055, 4,101,513, and 4,161,478. The sulfonium salts of elements of Group VIa of the Periodic Table of Elements include triarylsulfonium hexafluoroantimonates. The amount of the polymerization initiator is preferably 0.5 to 30 parts by weight, particularly 2 to 20 parts by weight, per 100 parts by weight of the monomers. When the amount is less than 0.5 parts by weight, the ultraviolet-curing rate is remarkably reduced. It is preferred that the reaction initiator is not a metal complex but an organic compound.

The flat layer may contain a binder, which may be compatible or incompatible with the monomer. The binder may be selected from various resins capable of forming a film. The resin for the binder is preferably excellent in adhesion to the electrode or the substrate. The amount of the binder is preferably 10 to 600 parts by weight per 100 parts by weight of the monomers. A solvent for dissolving or dispersing the monomers and the binder may be any known one.

The resin for the binder may be any resin known in the art. A high-heat-resistant resin is generally used as the binder in the present invention, and examples thereof include polyamide resins; polyester resins; epoxy resins; polyurethane resins; polyacryl resins such as polymethyl methacrylate, polyacrylamide, and polystyrene-2-acrylonitrile; vinyl resins such as polyvinylpyrrolidone; polyvinyl chloride resins such as vinyl chloride-vinyl acetate copolymers; polycarbonate resins; polystyrenes; polyphenylene oxides; cellulose-based resins such as methylcellulose, ethylcellulose, carboxymethylcellulose, cellulose acetate hydrogen phthalate, cellulose acetate, cellulose acetate propionate, cellulose acetate butyrate, and cellulose triacetate; polyvinyl alcohol resins such as partially saponified derivatives of polyvinyl alcohol, polyvinyl butyral, etc.; petroleum resins; rosin derivatives; cumarone-indene resins; terpene-based resins; polyolefin resins such as polyethylene and polypropylene; etc. The binder may be a known water-soluble and/or water-dispersible polymer. It is preferred that such a polymer is water-dispersible and can be made water-insoluble by drying.

The flat layer may be formed by the steps of dissolving or dispersing the monomer in an appropriate solvent to prepare a coating liquid; applying the coating liquid to the first substrate; and drying the applied liquid. The binder may be dissolved or dispersed in a solvent with a monomer. The thickness of the flat layer is generally 0.05 to 50 μm, preferably 0.1 to 20 μm, more preferably 0.5 to 10 μm. When the thickness of the flat layer is more than 50 μm, the flat layer is poor in flexibility and thus easily damaged or cracked during the production process. When the thickness of the flat layer is less than 0.05 μm, the flatness of the flat layer-carrying first substrate may be insufficient depending on the surface conditions of the first substrate. The flat layer may comprise 2 or more layers.

A hardening agent may be added to the flat layer. Organic solvent-soluble polymers may be hardened by using hardening agents described in JP 61-199997 A, JP 58-215398 A, etc. Hardening agents described in U.S. Pat. No. 4,678,739, column 41, JP 59-116655 A, JP 62-245261 A, JP 61-18942 A, etc. are suitable for hardening water-soluble polymers. Examples of the hardening agents include aldehyde-based hardening agents such as formaldehyde; aziridine-based hardening agents; epoxy-based hardening agents; vinylsulfone-based hardening agents such as N,N′-ethylene-bis(vinylsulfonylacetamido)ethane; N-methylol-based hardening agents such as dimethylolurea; high-molecular-weight hardening agents as described in JP 62-234157 A; etc.

Additives such as an antioxidant, an antistatic agent, a dispersing agent, a stabilizer, and a lubricant may be added to the flat layer. A drying agent may be added to the monomer unless hardening is practically hindered. The drying agent may not be particularly restrictive, but any agent commonly used in the field of semiconductors may be used. Examples of the drying agents include alkaline metal oxides, alkaline earth metal oxides, sulfates, metal halides, perchlorates, organic compounds, organic metal compounds, etc.

Various surfactants may be added to the coating liquid as a coating aid, an antistatic agent, or a transporting lubricant, etc. The surfactants include nonionic surfactants, anionic surfactants, ampholytic surfactants, cationic surfactants, etc. Specific examples of the surfactants are described in JP 62-173463 A, JP 62-183457 A, etc. Organic fluoro compounds may be used as the surfactants. Typical examples of the organic fluoro compounds include fluorine-containing surfactants described in JP 57-9053 B, column 8 to 17, JP 61-20944 A, JP 62-135826 A, etc.; fluorine-containing oils such as fluorine oils; and hydrophobic fluorine compounds including solid fluororesins such as tetrafluoroethylene resins. Known releasing agents may be used as the surfactants, examples thereof including solid or wax agents such as polyethylene wax, amide wax, silicone resin powders, and fluororesin powders; surfactants such as fluorine-containing surfactants and phosphate-based surfactants; oil agents such as paraffin oils, silicone oils, and fluorine oils; etc. The silicone oils may be unmodified or modified. For example, the silicone oils may be carboxy-modified, amino-modified, epoxy-modified, polyether-modified, or alkyl-modified. The modified silicone oils may be used alone or in combination, and examples thereof include modified silicone oils described in Technical Data “Modified Silicone Oils”, pages 6 to 18B, Silicone Division of Shin-Etsu Chemical Co., Ltd. In the case of using an organic solvent-soluble binder in the flat layer, amino-modified silicone oils having a group capable of reacting with the crosslinking agent in the binder, such as a group capable of reacting with an isocyanate group, are preferred. In the case of using a water-soluble binder, a carboxy-modified silicone oil such as X-22-3710 (trade name) available from the Silicone Division of Shin-Etsu Chemical Co., Ltd., or an epoxy-modified silicone oil such as KF-100T (trade name) available from the Silicone Division of Shin-Etsu Chemical Co., Ltd. is preferably emulsified in the water-soluble binder.

The coating liquid may be applied by a known method such as an extrusion coating method and a roll coating method, using a double roll coater, a slit coater, an air knife coater, a wire bar coater, a slide hopper, spray coating, a blade coater, a doctor coater, a squeeze coater, a reverse roll coater, a transfer roll coater, an extrusion coater, a curtain coater, a die coater, a gravure roll, etc.

The hardening of the flat layer is generally explained below without intention of restricting the scope of the present invention. In the case of hardening the flat layer by electron beam irradiation, an electron beam accelerator is preferably used at an accelerating voltage of 100 to 1,000 kV and a one-pass absorption dose of 0.5 to 20 Mrad, from the viewpoints of penetrability and hardening. The accelerating voltage is more preferably 100 to 300 KV. When the accelerating voltage or the electron beam dose is too low, electron beams are so poor in penetrability that the inside of the flat layer is not sufficiently hardened. On the other hand, when the accelerating voltage or the electron beam dose is too high, the energy efficiency, the strength of the substrate, and the layer quality are low, the resins or the additives being likely to be decomposed. The electron beam accelerator may be an electrocurtain system, a scanning-type accelerator, a double-scanning-type accelerator, etc. When the oxygen concentration of the atmosphere is too high in the electron beam irradiation process, the hardening of the electron beam-curing organic compound is prevented. Thus, the oxygen concentration is preferably decreased by replacing oxygen with an inert gas such as nitrogen, helium and carbon dioxide. The oxygen concentration is preferably 600 ppm or less, more preferably 400 ppm or less.

A lamp having an intensity of 80 W/cm or more is preferably used for irradiating ultraviolet rays to harden the flat layer. Examples of such lamps include low-pressure mercury lamps, middle-pressure mercury lamps, high-pressure mercury lamps, metal halide lamps, etc. Ozoneless-type lamps, which generate less ozone, may be used for irradiating ultraviolet rays.

Common hot-air heaters, ceramic heaters, hot plates, heating rollers, laminators, hot stamps, thermal heads, laser lights, etc. may be used for hardening the flat layer by heating. Examples of the laser lights include ion gas lasers such as argon laser and krypton laser; metal vapor lasers such as copper laser, gold laser and cadmium laser; solid lasers such as ruby laser and YAG laser; semiconductor lasers such as gallium-arsenic laser that emit light in the infrared range of 750 to 870 nm; etc. The semiconductor lasers are practically preferred from the viewpoints of the size, cost, stability, reliability, durability, and easy modulation. In the case of using laser, the flat layer or the adjacent layer preferably contains a material capable of effectively absorbing the laser light. When such an absorbing material is irradiated with a laser light, the material converts the light energy into thermal energy. The thermal energy is transferred to the adjacent monomer molecules, whereby the monomer molecules are heated at the curing temperature. A layer of the absorbing material may be formed between the flat layer and the first substrate. The absorbing material may be mixed with the monomer.

The inorganic oxides and the inorganic nitrides for the flat layer are described below. One or more materials selected from metal oxides such as silicon oxide, germanium oxide, zinc oxide, aluminum oxide, titanium oxide, and copper oxide, and metal nitrides such as silicon nitride, germanium nitride, and aluminum nitride are preferably used for forming an insulating flat layer having a linear thermal expansion coefficient of 20 ppm/° C. or less. The insulating flat layer of metal oxides and/or metal nitrides preferably has a thickness of 10 nm to 10 μm. When the thickness is less than 10 nm, the insulating flat layer has poor insulation. On the other hand, when the thickness is more than 10 μm, the insulating flat layer is likely to be cracked to form pinholes, thereby exhibiting reduced insulation.

Unlimited examples of the methods for forming the insulating flat layer of a metal oxide and/or a metal nitride include dry methods such as vapor deposition methods, sputtering methods, and CVD methods; wet methods such as sol-gel methods; and methods of applying a coating liquid prepared by dispersing particles of a metal oxide and/or a metal nitride in a solvent.

The flat layer preferably has a linear thermal expansion coefficient of 20 ppm/° C. or less. When the linear thermal expansion coefficient of the flat layer is more than 20 ppm/° C., the flat layer is often cracked or peels off by cooling or heating after the thermal transferring step, resulting in poor durability.

Preferable plastic materials having linear thermal expansion coefficients of 20 ppm or less are polyimides and liquid crystal polymers. The properties of the plastic materials are described in detail in Plastic Databook, edited by “Plastic” Editorial Department, Asahi Kasei AMIDAS, etc.

Before forming the flat layer, the first substrate may be surface-treated or coated with an undercoating layer to prevent peeling of the flat layer and to increase the durability if necessary. Further, an insulating layer may be formed on the first substrate. The insulating layer is not particularly restricted, and the flat layer may act as the insulating layer.

The shape, structure, size, etc. of the first substrate are not particularly limited, and may be appropriately determined in accordance with purposes and applications of the organic electroluminescent device. In general, the first substrate is preferably in a shape of plate or sheet. The first substrate may be flexible.

To prevent the penetration of water and oxygen, which deteriorates the durability of the organic electroluminescent device, the first substrate preferably has a water permeability of 0.01 g/m²· day or less, and an oxygen permeability of 0.01 cc/m²· day or less. The water permeability is measured according to JIS K7129B, mainly by an MOCON method, and the oxygen permeability is measured according to JIS K7126B, mainly by an MOCON method.

(2) Second substrate

After the single- or multi-layered organic layer is formed on the first substrate by a peeling transfer method or by its repetition, the second substrate may be laminated onto the upper surface of the organic layer. The second substrate preferably has a surface to be laminated to the organic layer, whose maximum roughness Rmax is 0 to 50 according to JIS B 0601-1982, assuming that the organic layer formed on the first substrate has a thickness of 100. The maximum surface roughness Rmax of the second substrate is more preferably 0 to 25, more preferably 0.0001 to 10.

The second substrate preferably has a linear thermal expansion coefficient of 20 ppm/° C. or less. Specific examples of materials for such a second substrate may be the same as those for the first substrate, which are described in “(1) First substrate.” The flat layer described above is preferably formed on the second substrate. Preferred examples of the thickness, water permeability, etc. of the second substrate are the same as those of the first substrate.

The second substrate may be transparent or opaque. At least one of the first and second substrates is preferably colorless transparent to reduce the scattering and attenuation of light emitted from the organic layer.

[2] Production of Organic Electroluminescent Device

In the production of an organic electroluminescent device according to the present invention, the transfer material is prepared by forming at least one organic layer on a support or a plate having a pattern, superposed on the first substrate such that the organic layer of the transfer material faces the coating surface (electrode) of the first substrate, and heated and/or pressed, followed by the separation of the support or the patterned plate from the organic layer, so that the organic layer is transferred onto the coating surface (electrode) of the first substrate. Two or more transfer materials having the same or different organic layers may be used in the production method.

After the organic layer is transferred onto the first substrate via the electrode, the second substrate having an electrode formed at least partially thereon is preferably superposed on the first substrate, so that the electrode of the second substrate is in contact with the organic layer transferred to the first substrate. Another organic layer may be formed on the electrode on the second substrate by a coating method, etc. before the second substrate is superposed on the first substrate.

In the peeling transfer method, the organic layer softened by heating and/or pressing is laminated to the electrode on the first substrate, and the support or the plate is separated from the organic layer, so that only the organic layer remains on the first substrate. A laminate of the transfer material and the first substrate may be heated and/or pressed by a known method using a laminator, an infrared heater, a thermal head, a hot plate, a pressing apparatus, etc. First Laminator VA-400III available from Taisei Laminator K. K., a thermal head for thermal transfer printing, a hot plate pressing apparatus, etc. may be used as the laminator.

The transfer temperature may be changed depending on the materials of the organic layers and the heating member. In general, the transfer temperature is preferably 40 to 250° C., more preferably 50 to 200° C., particularly 60 to 180° C. The preferred transfer temperature range may be elevated as the heat resistance of the heating member, the transfer material and the first substrate increases. In the case of successively using a plurality of transfer materials, the transfer temperature at the preceding transferring step is preferably equal to or higher than at the following transferring step. In a case where a transfer material having plural organic layers is used such that the organic layers are successively transferred, the transfer temperature at the preceding transferring step is preferably equal to or higher than at the following transferring step.

The transfer pressure may be changed depending on the materials of the organic layers and the pressing apparatus. In general, the transfer pressure is preferably 0 to 10 t/cm², more preferably 0 to 5 t/cm², particularly 0 to 2 t/cm². The preferred transfer pressure range may be increased as the pressure resistance of the press member, the transfer material and the first substrate increases.

It is preferred that the organic layer or high-molecular-weight components therein have glass transition temperatures or flow-starting temperatures of higher than 40° C., and that the organic layer is transferred at a transfer temperature of 40° C. or lower. In the case of transferring a plurality of organic layers, the organic layers may contain common components.

The first substrate and/or the transfer material may be preheated before the transferring step. The preheating temperature is preferably at least 30° C. and at highest the transfer temperature +20° C. The peeling temperature, at which the support or the plate is peeled off, is preferably at least −50° C. and at highest the transfer temperature.

After peeling the support or the plate, the transferred organic layer may be heated. When the transfer material is superposed on the first substrate and heated, pressure may be applied to a stack of the transfer material and the first substrate.

When the transfer material is superposed on the first substrate, a superposing angle of the transfer material to the first substrate is preferably relatively large to reduce the inclusion of air bubbles. Further, when the support or the plate is peeled from the organic layer, a peeling angle of the support or the plate to the organic layer is preferably relatively large.

The transfer material and/or the first substrate are preferably in the form of a continuous web. The transfer material used for the production of the organic electroluminescent device of the present invention comprises an organic layer formed on the support or the plate. Plural organic layers having the same or different compositions may be successively formed on the support or the plate. The organic layer preferably contains a light-emitting organic compound or a carrier-transporting organic compound.

In the present invention, the peeling transfer method may be repeated to laminate plural organic layers having the same or different compositions on the first substrate via the electrode. In a case where the organic layers have the same composition, voids due to poor transfer and peeling can be prevented in the resultant organic layer. The light-emitting efficiency of the organic electroluminescent device can be improved by forming organic layers having different functions. For example, a laminate of a transparent conductive layer/a light-emitting organic layer/an electron-transporting organic layer/an electron-injecting layer/a rear-surface electrode, or a laminate of a transparent conductive layer/a hole-injecting layer/a hole-transporting organic layer/a light-emitting organic layer/an electron-transporting organic layer/an electron-injecting layer/a rear-surface electrode can be formed on the first substrate in this or opposite order by the transfer method of the present invention.

The organic layer transferred onto the first substrate via the electrode or another organic layer transferred onto the organic layer is preferably re-heated and/or re-pressed to improve adhesion between the organic layer and the first substrate or between the organic layers. The re-heating temperature is preferably within a range of the transfer temperature +50° C. The pressure applied in the re-pressing is preferably within a range of the transfer pressure ±100%.

The transferred organic layer may be surface-treated before the subsequent transferring step to improve adhesion, thereby preventing the organic layer transferred onto the substrate from being reversely transferred onto another organic layer, which is to be transferred onto the organic layer on the substrate, in the next transferring step. Examples of such surface treatments include activation treatments such as corona discharge treatments, flame treatments, glow discharge treatments, and plasma treatments. In the case of utilizing the surface treatment, the transfer temperature at the preceding transferring step may be lower than at the following transferring step, unless the reverse transfer occurs.

An apparatus used in the method of the present invention preferably comprises a means for supplying the transfer material prepared by forming the organic layer on the support or the plate by a wet method, etc.; a transfer means for heating and/or pressing the transfer material on the first substrate; and a means for peeling the support or the plate from the organic layer.

The apparatus preferably has a means for preheating the transfer material and/or the first substrate before they are supplied to the transfer means. Further, the apparatus may have a cooling means downstream of the transfer means. A means for controlling a superposing angle may be disposed upstream of the transfer means to increase the angle of the transfer material supplied onto the first substrate. A peeling angle-controlling means may be disposed downstream of the transfer means or the cooling means to increase the peeling angle of the support or the plate to the organic layer. The details of the apparatus for producing the organic electroluminescent device are described in JP 2002-260854 A, JP 2002-289346 A, etc.

[3] Transfer Material

The structure and components of the transfer material are described below.

(1) Structure

The transfer material comprises the support or the plate having a pattern, and at least one organic layer formed thereon. In the case of using the plate for forming plural organic layers on the first substrate, a plurality of transfer materials each having an organic layer are preferably prepared. In the case of using the support for forming plural organic layers on the first substrate, a plurality of transfer materials each having an organic layer may be prepared, or alternatively a web transfer material having an organic layer laminate may be prepared. The web transfer material can transfer the organic layers successively without changing transfer materials.

The transfer material having plural organic layers can form a multi-layered film on the first substrate by one transferring step. When the interfaces between the organic layers are not uniform, holes or electrons are unevenly transported. Thus, a method for forming the organic layers on the support or the plate is carefully selected from wet methods and dry methods such as vapor deposition methods to obtain uniform interfaces.

(2) Support

Materials for the support are not particularly limited as long as they have chemical and thermal stability. Specific examples of such materials include glass; metals such as aluminum, copper, stainless steel, gold and silver; plastics such as polyimides, liquid crystal polymers, fluororesins including tetrafluoroethylene resins (PTFE) and trifluorochloroethylene resins (PCTFE), polyesters including polyethylene terephthalate and polyethylene naphthalate (PEN), polycarbonates, polyether sulfones (PES), polyolefins including polyethylene and polypropylene, polyarylates, and rigid polyvinyl chlorides; etc. The support may be composed of one material or a laminate of plural materials. The support is preferably a glass sheet, a polyethylene terephthalate sheet, or a laminate containing any of them, from the viewpoints of workability and cost.

The thickness of the support is not particularly limited as long as it is thermally conductive and can transfer the organic layer. The continuous web transfer material preferably has a thin support for miniaturization. The thickness of the support is generally 3 to 300 μm, preferably 3 to 200 μm, particularly 4 to 100 μm, though depending on its material.

(3) Plate

The plate having a pattern may be a usual printing plate such as a relief printing plate, a planographic plate, an intaglio plate, and a stencil printing plate. The pattern of the plate may have any desired shape. When the relief printing plate having a pattern and a recessed portion is used, the first substrate comes into contact only with the pattern of the relief printing plate. Examples of the mechanically produced relief printing plates include a typographic printing plate (typographical composition) including a phototypographic printing plate; a lead plate formed by pouring an alloy into a typographic printing plate; a wood block; a plastic plate; a rubber plate; etc. The relief printing plate may be chemically produced. For example, the relief printing plate may be an electroplated typographic printing plate.

Preferable relief printing plates include a carved relief printing plate formed by carving a glass plate or a metal sheet, and an etched relief printing plate formed by etching desired portions of a copper plate or cylinder. The carved relief printing plate may be a relief printing plate electrically engraved by a method of photoelectrically scanning an original copy to generate a current signal for driving a carving apparatus, and carving a plate by a diamond needle in response to the current signal. The carved relief printing plate may also be a laser-carved relief printing plate prepared by using laser beams for carving a plate. A line engraving plate may be used to form a line drawing without gradation, and a network relief printing plate or an electrically engraved relief printing plate is used to form image with gradation such as photographs.

The pattern of the relief printing plate is formed such that the organic layer is transferred in a desired pattern. For example, the relief printing plate may have a plurality of projections each having a rectangular, square or trapezoidal cross section on a base. With such a relief printing plate, the contact area of each projection is not limited as long as it is not crushed at the transferring step. The total contact area of the projections may be determined depending on the transferring conditions and the pattern shape, and is preferably 5 to 100, more preferably 5 to 95, assuming that the surface area of the plate is 100. The height of each projection is preferably 0.5 to 50 μm. When the height of each projection is less than 0.5 μm, the organic layer is likely to be transferred into the recesses.

The planographic plate macroscopically has a pattern area and a non-pattern area on the same plane. For instance, when the organic layer is formed on the planographic plate by using a coating liquid, the planographic plate made of glass or a metal may be made lyophilic in the pattern area and lyophobic in the non-pattern area. Thus, the planographic plate is prepared not mechanically but chemically. Examples of the planographic plates include lithographs mainly composed of calcium carbonate; planographic metal plates of zinc, aluminum, etc.; multi-layered planographic plates prepared by forming two different metal layers on a support; and collotype plates prepared by applying a sensitizing solution mainly composed of gelatin to a glass plate, etc. In the case of using the collotype plate, the negative plate may be printed to harden the exposed portions, and an organic layer-coating liquid may be absorbed in unhardened portions to form the pattern. The unhardened portions may be swollen by the absorption of the coating liquid. In the case of using the planographic plate, the first substrate comes into contact with almost entire surface of the transfer material.

Contrary to the relief printing plate, the intaglio plate has a recessed pattern and a flat non-pattern area. In the case of using the intaglio plate, the organic layer is formed on the entire surface of the plate, and the organic layer formed in the non-pattern area is removed (wiped or scraped off), so that the organic layer remains only in the recessed pattern. Examples of the mechanically produced intaglio plates include a carved intaglio plate prepared by carving a copper plate, etc. The carved intaglio plate may be an electrically engraved plate prepared by the above electric engraving process. The carved intaglio plate may also be a laser-carved intaglio plate. Examples of the chemically produced intaglio plates include a gravure plate for photo-image prepared by etching a desired part of a copper plate or cylinder.

The stencil printing plate is a film or a sheet having a penetrating pattern. In the case of using the stencil printing plate, the patterned through-holes of the plate are filled with a dry organic film. Examples of the stencil printing plates include a mimeographic plate of a netting having a network pattern; and a silkscreen comprising a silk net having a non-pattern area filled with a resin, etc.

The relief printing plate is preferably used as a patterned plate, because it suffers from little inclusion of air bubbles at the transferring step, and little material loss in the production of the patterned plate and the transfer material.

When the relief printing plate or the intaglio plate is used such that the organic layer is transferred onto the first substrate accurately in a desired pattern, the plate is preferably tapered from a coating surface to a bottom surface.

Materials for the plate are not particularly limited as long as they are chemically and thermally stable. The plate materials may be the same as the support materials. The plate may be composed of one material or a laminate of plural materials. The plate preferably comprises a glass sheet, an aluminum sheet, a copper sheet, a stainless steel sheet, or a laminate thereof, from the viewpoints of workability and cost. The thickness of the plate is not particularly limited and may be determined depending on the production apparatus. The plate preferably has a larger thickness as long as it can be repeatedly used without practical difficulty. The thickness of the plate is generally 0.5 to 5 mm though it may be changed depending on the plate material. The structure and size of the plate are not particularly restricted and may be appropriately selected in accordance with the specification, application, etc. of the production apparatus.

A flat layer may be formed on the support or the plate to improve coatability and detachability. Further, the support or the plate may be subjected to a water-repellent treatment as long as it does not deteriorate the coatability.

(4) Formation of Organic Layer on Support or Plate

In a case where the organic layer contains a high-molecular-weight compound, the organic layer is preferably formed on the support or the patterned plate by a wet method. In the wet method, materials for the organic layer are generally dissolved in an organic solvent at a desired concentration, and the resultant solution is applied to the support or the patterned plate. An application method is not particularly limited, as long as it can form an organic layer with a uniform thickness distribution at a dry thickness of 200 nm or less. Such application methods may be a spin-coating method, a gravure-coating method, a dip-coating method, a casting method, a die-coating method, a roll-coating method, a bar-coating method, an extrusion-coating method, an ink-jet-coating method, etc. Preferable among them are a roll-to-roll extrusion-coating method having a high productivity. In a case where the organic layer is composed of low-molecular-weight compounds, the organic layer may be formed by the above application methods or by a vapor deposition method.

(5) Organic Layers

Organic layers forming the organic electroluminescent device are classified to a light-emitting organic layer, an electron-transporting organic layer, a hole-transporting organic layer, an electron-injecting layer, a hole-injecting layer, etc. depending on their functions. The organic layers may further include various layers for improving light emission. Specific examples of compounds used for the organic layers are described in Organic EL Display (Technotimes Co., Separate Volume of Monthly Display, the October issue of 1998), etc.

The glass transition temperatures of the organic layer or high-molecular-weight components therein are preferably from 40° C. to the transfer temperature +40° C., more preferably from 50° C. to the transfer temperature +20° C., particularly from 60° C. to the transfer temperature. The flow-starting temperatures of the organic layer or high-molecular-weight components therein are preferably from 40° C. to the transfer temperature +40° C., more preferably from 50° C. to the transfer temperature +20° C., particularly from 60° C. to the transfer temperature. The glass transition temperature can be measured by a differential scanning calorimeter (DSC). The flow-starting temperature can be measured by Flow Tester CFT-500 available from Shimadzu Corporation, etc.

(a) Light-emitting Organic Layer

The light-emitting organic layer comprises at least one light-emitting compound. Though not restrictive, the light-emitting compound may be a fluorescent compound or a phosphorescent compound. The fluorescent compound and the phosphorescent compound may be used in combination. In the present invention, the phosphorescent compound is preferably used from the viewpoints of brightness and light-emitting efficiency.

Examples of the fluorescent compounds include benzoxazole derivatives; benzoimidazole derivatives; benzothiazole derivatives; styrylbenzene derivatives; polyphenyl derivatives; diphenylbutadiene derivatives; tetraphenylbutadiene derivatives; naphthalimido derivatives; coumarin derivatives; perylene derivatives; perynone derivatives; oxadiazole derivatives; aldazine derivatives; pyralidine derivatives; cyclopentadiene derivatives; bis(styryl)anthracene derivatives; quinacridon derivatives; pyrrolopyridine derivatives; thiadiazolopyridine derivatives; styrylamine derivatives; aromatic dimethylidine compounds; metal complexes such as 8-quinolinol derivative-metal complexes and rare-earth metal complexes; light-emitting polymer compounds such as polythiophene derivatives, polyphenylene derivatives, polyphenylenevinylene derivatives and polyfluorene derivatives; etc. The fluorescent compounds may be used alone or in combination.

The phosphorescent compound preferably utilizes triplet excitons for light emission. The phosphorescent compound is preferably an ortho-metallation complex or a porphyrin complex. The porphyrin complex is preferably a porphyrin-platinum complex. The phosphorescent compounds may be used alone or in combination.

The ortho-metallation complexes used in the present invention may be such compounds as described in Akio Yamamoto, “Metalorganic Chemistry, Foundations and Applications,” pages 150 to 232, Shokabo Publishing Co., Ltd., (1982); H. Yersin, “Photochemistry and Photophysics of Coordination Compounds,” pages 71 to 77 and 135 to 146, Springer-Verlag, Inc. (1987), etc. Although ligands of the ortho-metallation complexes are not particularly limited, the ortho-metallation complexes generally have particular ligands. Preferred examples of the particular ligands include 2-phenylpyridine derivatives, 7,8-benzoquinoline derivatives, 2-(2-thienyl)pyridine derivatives, 2-(1-naphthyl)pyridine derivatives and 2-phenylquinoline derivatives. The derivatives may have substituents. The ortho-metallation complexes may have other ligands than the particular ligands. Center metal atoms of the ortho-metallation complexes may be selected from transition metals. The center metals are preferably rhodium, platinum, gold, iridium, ruthenium or palladium. The organic compound layers comprising such ortho-metallation complexes are excellent in brightness and light-emitting efficiency. Specific examples of such ortho-metallation complexes are described in JP 2002-319491 A.

The ortho-metallation complexes used in the present invention may be synthesized by known methods disclosed in Inorg. Chem., 30, 1685, 1991; Inorg. Chem., 27, 3464, 1988; Inorg. Chem., 33, 545, 1994; Inorg. Chim. Acta, 181, 245, 1991; J. Organomet. Chem., 335, 293, 1987; J. Am. Chem. Soc., 107, 1431, 1985; etc.

Though not restrictive, the amount of the light-emitting compound in the light-emitting organic layer is, for instance, preferably 0.1 to 70% by mass, more preferably 1 to 20% by mass. When the amount of the light-emitting compound is less than 0.1% by mass or more than 70% by mass, the addition of the light-emitting compound does not provide sufficient effects.

The light-emitting organic layer may contain host compounds, hole-transporting materials, electron-transporting materials, electrically inactive polymer binders, etc., if necessary. Incidentally, the functions of these materials may be achieved even with one compound. For instance, carbazole derivatives can act not only as host compounds but also as hole-transporting materials.

The host compounds are compounds causing energy transfer from their excited state to the light-emitting compounds, resulting in accelerating the light emission of the light-emitting compounds. Specific examples of the host compounds include carbazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stilbene derivatives, silazane derivatives, aromatic tertiary amine compounds, styrylamine compounds, aromatic dimethylidene compounds, porphyrin compounds, anthraquinodimethane derivatives, anthrone derivatives, diphenylquinone derivatives, thiopyran dioxide derivatives, carbodimide derivatives, fluorenylidenemethane derivatives, distyrylpyrazine derivatives, anhydrides derived from heterocyclic tetracarboxylic acids having a structure such as naphthalene and perylene, phthalocyanine derivatives, 8-quinolinol derivative-metal complexes, metallophthalocyanines, metal complexes containing benzoxazole or benzothiazole ligands, polysilane compounds, poly(N-vinylcarbazole) derivatives, aniline copolymers, electrically conductive polymers and oligomers such as oligothiophenes, polythiophenes and their derivatives, polythiophene derivatives, polyphenylene derivatives, polyphenylenevinylene derivatives, polyfluorene derivatives, etc. The host compounds may be used alone or in combination. The amount of the host compound in the light-emitting organic layer is preferably 0 to 99.9% by mass, more preferably 0 to 99.0% by mass.

Though not restrictive, the hole-transporting materials may be low- or high-molecular-weight materials if they have any of functions of injecting holes from the anode into the light-emitting organic layer, transporting holes and blocking electrons from the cathode. Examples of the hole-transporting materials include carbazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stilbene derivatives, silazane derivatives, aromatic tertiary amine compounds, styrylamine compounds, aromatic dimethylidyne compounds, porphyrin compounds, polysilane compounds, poly(N-vinylcarbazole) derivatives, aniline copolymers, electrically conductive polymers and oligomers such as oligothiophenes, polythiophenes and their derivatives, polythiophene derivatives, polyphenylene derivatives, polyphenylenevinylene derivatives, polyfluorene derivatives, etc. These hole-transporting materials may be used alone or in combination. The amount of the hole-transporting material in the light-emitting organic layer is preferably 0 to 99.9% by mass, more preferably 0 to 80.0% by mass.

The electron-transporting materials are not particularly limited as long as they have any of functions of injecting electrons from the cathode into the light-emitting organic layer, transporting electrons, and blocking holes from the anode. Examples of the electron-transporting materials include triazole derivatives, oxazole derivatives, oxadiazole derivatives, fluorenone derivatives, anthraquinodimethane derivatives, anthrone derivatives, diphenylquinone derivatives, thiopyran dioxide derivatives, carbodimide derivatives, fluorenylidenemethane derivatives, distyrylpyrazine derivatives, anhydrides derived from heterocyclic tetracarboxylic acids having structures such as naphthalene and perylene, phthalocyanine derivatives, 8-quinolinol metal complexes and derivatives thereof, metallophthalocyanines, metal complexes containing benzoxazole or benzothiazole ligands, aniline copolymers, electrically conductive polymers and oligomers such as oligothiophenes, polythiophenes and their derivatives, polythiophene derivatives, polyphenylene derivatives, polyphenylenevinylene derivatives, polyfluorene derivatives, etc. These electron-transporting materials may be used alone or in combination. The amount of the electron-transporting material in the light-emitting organic layer is preferably 0 to 99.9% by mass, more preferably 0 to 80.0% by mass.

Examples of the polymer binders include polyvinyl chloride, polycarbonates, polystyrene, polymethyl methacrylate, polybutyl methacrylate, polyesters, polysulfones, polyphenylene oxide, polybutadiene, hydrocarbon resins, ketone resins, phenoxy resins, polyamides, ethyl cellulose, polyvinyl acetate, ABS resins, polyurethanes, melamine resins, unsaturated polyesters, alkyd resins, epoxy resins, silicone resins, polyvinyl butyral, polyvinyl acetal, etc. The polymer binders may be used alone or in combination. When the polymer binder is contained, a large-area light-emitting organic layer can be easily formed by a wet method.

The thickness of the light-emitting organic layer is preferably 10 to 200 nm, more preferably 20 to 80 nm. When the thickness exceeds 200 nm, driving voltage is likely to rise. On the other hand, when the thickness of the light-emitting organic layer is less than 10 nm, short-circuiting is likely to occur in the organic electroluminescent device.

(b) Hole-transporting Organic Layer

The organic electroluminescent device may comprise a hole-transporting organic layer made of the above hole-transporting material, if necessary. The hole-transporting organic layer may contain the above polymer binder. The thickness of the hole-transporting organic layer is preferably 10 to 200 nm, more preferably 20 to 80 nm. When the thickness of the hole-transporting organic layer exceeds 200 nm, driving voltage is likely to rise. On the other hand, when it is less than 10 nm, short-circuiting is likely to occur in the organic electroluminescent device.

(c) Electron-transporting Organic Layer

The organic electroluminescent device may have an electron-transporting organic layer made of the above electron-transporting material, if necessary. The electron-transporting organic layer may contain the above polymer binder. The thickness of the electron-transporting organic layer is preferably 10 nm to 200 nm, more preferably 20 to 80 nm. When the dry thickness exceeds 200 nm, driving voltage is likely to rise. On the other hand, when it is less than 10 nm, short-circuiting is likely to occur in the organic electroluminescent device.

(d) Solvent for Coating Liquid

In a case where the organic layer is formed by a wet film-forming method, a solvent may be used for dissolving materials for the organic layer to prepare a coating liquid. The solvents are not particularly restrictive, but may be properly selected depending on the types of the hole-transporting materials, the ortho-metallated complexes, the host materials, the polymer binders, etc. Examples of the solvents include halogen solvents such as chloroform, tetrachloromethane, dichloromethane, 1, 2-dichloroethane and chlorobenzene; ketone solvents such as acetone, methyl ethyl ketone, diethyl ketone, n-propyl methyl ketone and cyclohexanone; aromatic solvents such as benzene, toluene and xylene; ester solvents such as ethyl acetate, n-propyl acetate, n-butyl acetate, methyl propionate, ethyl propionate, y-butyrolactone and diethyl carbonate; ether solvents such as tetrahydrofuran and dioxane; amide solvents such as dimethylformamide and dimethylacetamide; dimethylsulfoxide; water; etc. The solid content of the coating liquid is not particularly limited, and the viscosity of the coating liquid may be selected depending on the wet film-forming method.

In the case of forming a plurality of organic layers, the transfer method of the present invention may be used with other methods. Examples of the other methods include dry methods such as a vapor deposition method and a sputtering method; wet methods such as a dipping method, a spin-coating method, a dip-coating method, a casting method, a die-coating method, a roll-coating method, a bar-coating method and a gravure-coating method; a printing method; etc.

[4] Organic Electroluminescent Device

(1) Structure

The structure of the organic electroluminescent device may be any one of the following laminate structures formed on the first substrate in the described orders or in opposite orders:

(a) Transparent conductive layer/light-emitting organic layer/rear-surface electrode;

(b) Transparent conductive layer/light-emitting organic layer/electron-transporting organic layer/rear-surface electrode;

(c) Transparent conductive layer/hole-transporting organic layer/light-emitting organic layer/electron-transporting organic layer/rear-surface electrode;

(d) Transparent conductive layer/hole-transporting organic layer/light-emitting organic layer/rear-surface electrode;

(e) Transparent conductive layer/light-emitting organic layer/electron-transporting organic layer/electron-injecting layer/rear-surface electrode;

(f) Transparent conductive layer/hole-injecting layer/hole-transporting organic layer/light-emitting organic layer/electron-transporting organic layer/electron-injecting layer/rear-surface electrode, etc.

A second substrate may be disposed on the organic layers, so that the organic layers are sandwiched by the substrates. The light-emitting organic layer comprises a fluorescent compound and/or a phosphorescent compound, and the emitted light is generally taken out from the transparent conductive layer. Specific examples of compounds used in each organic layer are described, for instance, in Organic EL Display (Technotimes Co., Separate Volume of “Monthly Display,” the October issue of 1998), etc.

(2) Electrode

The organic electroluminescent device preferably has one electrode constituted by a transparent conductive layer and the other electrode on a rear surface. Any transparent conductive layer and rear-surface electrode may be used as a cathode or an anode, which is determined by the composition of the organic electroluminescent device.

(a) Anode

The anode acts to supply holes to the light-emitting organic layer. The shape, structure and size of the anode is not restrictive but may be properly selected in accordance with the applications and purposes of the organic electroluminescent device.

The anode may be made of metals, alloys, metal oxides, electrically conductive compounds, mixtures thereof, etc. The anode is preferably made of a material having a work function of 4 eV or more. Examples of the materials for the anode include antimony-doped tin oxide (ATO); fluorine-doped tin oxide (FTO); semiconductive metal oxides such as tin oxide, zinc oxide, indium oxide, indium tin oxide (ITO) and indium zinc oxide (IZO); metals such as gold, silver, chromium and nickel; mixtures and laminates of the metals and conductive metal oxides; inorganic, conductive compounds such as copper iodide and copper sulfide; organic, conductive compounds such as polyaniline, polythiophene and polypyrrole; laminates of the organic, conductive compounds and ITO; etc.

The method for forming the anode on the substrate (first or second substrate) may be appropriately selected from wet methods such as a printing method and a coating method; physical methods such as a vacuum deposition method, a sputtering method and an ion-plating method; chemical methods such as CVD and plasma CVD; etc., depending on the materials used therefor. For example, when the anode is made of ITO, it may preferably be formed by a DC or RF sputtering method, a vapor deposition method, an ion-plating method, etc. In addition, when the anode is made of an organic, conductive compound, it may be formed by a wet method.

The patterning of the anode may be conducted by a chemical etching method such as a photolithography method, a physical etching method using laser beams, a vacuum vapor deposition method or a sputtering method with a mask, a lift-off method, a printing method, etc.

The thickness of the anode may be properly controlled depending on the material used therefor. The thickness of the anode is generally 10 nm to 50 μm, preferably 50 nm to 20 μm. The resistance of the anode is preferably 10⁶ Ω/square or less, more preferably 10⁵ Ω/square or less. When the resistance of the anode is 10⁵ Ω/square or less, the formation of bus line electrodes can provide a large-area, light-emitting device with excellent performance.

The anode may be colorless transparent, colored transparent, or opaque. In the case of using a transparent anode, the light transmittance of the anode is preferably 60% or more, more preferably 70% or more, to allow light emission from the anode side. The light transmittance can be measured by a known method using a spectrophotometer. Electrodes described in detail in Developments of Transparent Conductive Films, supervised by Yutaka Sawada, CMC Publishing Co., Ltd., 1999, etc. may be used as the transparent anode in the present invention. Particularly in the case of using a low-heat-resistance plastic substrate, it is preferable that the transparent anode is made of ITO or IZO and formed at a low temperature of 150° C. or lower.

(b) Cathode

The cathode acts to inject electrons into the light-emitting organic layer. The shape, structure and size of the cathode is not restrictive, and may be properly selected in accordance with the applications and purposes of the organic electroluminescent device.

The cathode may be made of metals, alloys, metal oxides, electrically conductive compounds, mixtures thereof, etc. The cathode is preferably made of a material having a work function of 4.5 eV or less. Examples of the materials used for the cathode include alkali metals such as Li, Na, K and Cs; alkaline earth metals such as Mg and Ca; gold; silver; lead; aluminum; sodium-potassium alloys; lithium-aluminum alloys; magnesium-silver alloys; indium; rare earth metals such as ytterbium; etc. Although the materials may be used alone, the cathode is preferably made of a plurality of materials to improve both of stability and electron injection property. Preferable among the above materials are alkali metals and alkaline earth metals from the viewpoint of the electron injection property, and aluminum-based materials from the viewpoint of stability during storage. Usable as the aluminum-based materials are aluminum itself and aluminum-based alloys and mixtures containing 0.01 to 10% by mass of alkali metals or alkaline earth metals, such as a lithium-aluminum alloy, a magnesium-aluminum alloy, etc.

In the case of allowing light emission from the cathode side, the cathode is substantially transparent. The light transmittance of the transparent cathode is preferably 60% or more, more preferably 70% or more. The cathode may have a two-layer structure comprising a thin film made of the above metal and a transparent conductive layer, to improve both electron injection and light transmittance. Metals for the thin films are described in detail in JP 2-15595 A and JP 5-121172 A. The thickness of the metal thin film is preferably 1 to 50 nm. It is difficult to form a uniform thin film having a thickness of less than 1 nm. When the thickness of the metal thin film is more than 50 nm, the light transmittance is reduced.

The transparent conductive layer in the two-layer structure may be made of any conductive or semiconductive, transparent material. The above-described materials for the anode may be used for the transparent conductive layer. In particular, the transparent conductive layer may comprise antimony-doped tin oxide (ATO), fluorine-doped tin oxide (FTO), tin oxide, zinc oxide, indium oxide, indium tin oxide (ITO), indium zinc oxide (IZO), etc. The thickness of the transparent cathode is preferably 30 to 500 nm. When the thickness of the transparent cathode is less than 30 nm, the conductivity or the semiconductivity is insufficient. The transparent cathode having a thickness of more than 500 nm is unsuitable for production.

The method for forming the cathode is not particularly limited, and may be a known method. The cathode is preferably formed in a vacuum apparatus. The method for forming the cathode may be appropriately selected from wet methods such as a printing method and a coating method; physical methods such as a vacuum deposition method, a sputtering method and an ion-plating method; chemical methods such as CVD and plasma CVD; etc., depending on the materials used therefor. In the case of using a plurality of materials for the cathode, the materials may be sputtered simultaneously or successively. A wet method may be used to form a cathode made of an organic conductive material. The patterning of the cathode can be carried out in the same manner as in the transparent, conductive layer.

A dielectric layer may be formed between the cathode and the light-emitting organic layer. The dielectric layer may be made of a fluorinated alkali or alkaline earth metal, having a thickness of 0.1 to 5 nm. The dielectric layer may be formed by a vacuum vapor deposition method, a sputtering method, an ion-plating method, etc.

(3) Light-emitting Organic Layer (electroluminescent layer)

Preferred examples of the light-emitting organic layer are described above. In the methods of the present invention for producing an organic electroluminescent device, the light-emitting organic layer is generally formed in a fine pattern manner. Methods of patterning the light-emitting organic layer are described below.

To form the organic layer in a fine pattern, a mask (fine mask) having openings in a fine pattern may be used. Though not restrictive, the mask is preferably made of highly durable, inexpensive materials such as metals, glass, ceramics, heat-resistant resins, etc. A plurality of materials may be used in combination. The thickness of the mask is preferably 2 to 100 μm, more preferably 5 to 60 μm, from the viewpoint of mechanical strength and the transfer accuracy of the organic layer.

The mask preferably has tapered openings having diameters decreasing from the transfer material side to the first substrate side, in order that the organic layer of the transfer material is laminated to the transparent conductive layer or the other organic layer precisely in a mask opening shape.

The patterned organic layer may be formed by the method of the present invention using a transfer material having projections formed by pressing. Preferably usable in this case is a method for producing an organic electroluminescent device, which comprises (a) a step of producing one or more transfer materials by forming at least one organic layer on each support; (b) a step of forming a pattern on at least one transfer material among one or more transfer materials by pressing it by a press with patterned roughness on the surface; and (c) a step of transferring at least one patterned organic layer onto a first substrate via an electrode by carrying out at least one operation of overlapping a patterned transfer material onto the first substrate via the electrode.

(4) Other Layers

The organic electroluminescent device preferably comprises a protective layer or a sealing layer to prevent the deterioration of light emission. The transfer material may further be provided with a parting layer between the organic layer and the support or the plate, and an adhesive layer between the organic layer and a transfer surface of the first substrate to improve transferability, unless the light-emitting performance is affected.

(a) Protective Layer

The organic electroluminescent device of the present invention may comprise a protective layer disclosed in JP 7-85974 A, JP 7-192866 A, JP 8-22891 A, JP 10-275682 A, and JP 10-106746 A, etc. The protective layer is generally formed on the uppermost surface of the organic electroluminescent device. For example, in the case of laminating the first substrate, the transparent conductive layer, the organic layers and the rear-surface electrode in this order, the uppermost surface is the outer surface of the rear-surface electrode. Further, for instance, in the case of laminating the first substrate, the rear-surface electrode, the organic layers and the transparent conductive layer in this order, the uppermost surface is the outer surface of the transparent conductive layer. The shape, size and thickness of the protective layer are not particularly limited. The protective layer may be made of any material that can prevent substances such as water and oxygen degrading the function of the organic electroluminescent device from entering or penetrating into the device. Silicon monoxide, silicon dioxide, germanium monoxide, germanium dioxide, etc. may be used for the protective layer.

Though not restrictive, the protective layer may be formed by a vacuum deposition method, a sputtering method, an activated sputtering method, a molecular beam epitaxy (MBE) method, a cluster ion beam method, an ion-plating method, a plasma polymerization method, a plasma CVD method, a laser CVD method, a thermal CVD method, a coating method, etc.

(b) Sealing Layer

The sealing layer is preferably formed in the organic electroluminescent device to prevent water and oxygen from entering or permeating into the device. Examples of materials for the sealing layer include copolymers of tetrafluoroethylene and at least one comonomer, fluorine-containing copolymers having cyclic structures in their main chains, polyethylene, polypropylene, polymethyl methacrylate, polyimides, polyureas, polytetrafluoroethylene, polychlorotrifluoroethylene, polydichlorodifluoroethylene, copolymers of chlorotrifluoroethylene or dichlorodifluoroethylene and other comonomers, moisture-absorbing substances having water absorption of 1% or more, moisture-resistant substances having a water absorption of 0.1% or less; metals such as In, Sn, Pb, Au, Cu, Ag, Al, Ti and Ni, metal oxides such as MgO, SiO, SiO₂, Al₂O₃, GeO, NiO, CaO, BaO, Fe₂O₃, Y₂O₃, and TiO₂, metal fluorides such as MgF₂, LiF, AlF₃, and CaF₂, liquid fluorinated carbons such as perfluoroalkanes, perfluoroamines and perfluoroethers, dispersions prepared by adding substances for adsorbing moisture or oxygen to liquid fluorinated carbons, etc.

The organic layers are preferably sealed by sealing means such as sealing plates and sealing containers to shield the device from moisture, oxygen, etc. outside. The sealing parts may be formed only on the rear-surface electrode. Alternatively, the entire organic electroluminescent device may be covered with the sealing means. The shape, size and thickness of the sealing means are not particularly limited as long as the sealing means can seal and shield the organic layer from outside air. The sealing means may be made of glass, metals such as stainless steel and aluminum, plastics such as polychlorotrifluoroethylene, polyesters and polycarbonates, ceramics, etc.

A sealing agent or an adhesive may be used to form the sealing means on the light-emitting structure. In the case of covering the entire light-emitting device with the sealing means, the sealing means may be heat-sealed without using a sealing agent. Usable as the sealing agent are ultraviolet-curing resins, thermosetting resins, two-part-type hardening resins, etc.

Further, a water-absorbing agent or an inert liquid may be charged between the organic electroluminescent device and the sealing container. Though not restrictive, the water-absorbing agents may be barium oxide, sodium oxide, potassium oxide, calcium oxide, sodium sulfate, calcium sulfate, magnesium sulfate, phosphorus pentoxide, calcium chloride, magnesium chloride, copper chloride, cesium fluoride, niobium fluoride, calcium bromide, vanadium bromide, molecular sieves, zeolite, magnesium oxide, etc. The inert liquids include paraffins, liquid paraffins, fluorine-containing solvents such as perfluoroalkanes, perfluoroamines and perfluorethers; chlorine-containing solvents; silicone oils, etc.

Light can be emitted from the light-emitting device of the present invention by applying DC voltage of usually 2 to 40 V, which may contain an AC component, if necessary, or DC current between the anode and the cathode. With respect to the driving method of the light-emitting device of the present invention, methods described in JP 2-148687 A, JP 6-301355 A, JP 5-29080 A, JP 7-134558 A, JP 8-234685 A, JP 8-241047 A, U.S. Pat. Nos. 5,828,429, 6,023,308, and Japanese Patent 2784615 may be utilized.

The present invention will be described in more detail below with reference to Examples without intention of restricting the scope of the present invention.

### EXAMPLES 1 to 8

(A) Preparation of Transfer Material

A coating liquid having a composition shown in Table 1 was applied to one surface of a 188-μm-thick support made of polyether sulfone available from Sumitomo Bakelite Co., Ltd. by a spin coater, and dried at room temperature, to form a light-emitting organic layer having a thickness of 15 nm, 40 nm or 80 nm, respectively, on the support, thereby preparing transfer materials 101, 102 and 103 respectively.

TABLE 1

| Composition | Mass Ratio |
|---|---|
| Polyvinyl carbazole (Mw = 63,000, available from | 40 |
| Aldrich Chemical Co.) | |
| Polyvinyl butyral (Mw = 140,000, S-Lec BX-5 | 25 |
| available from Sekisui Chemical Co., Ltd.) | |
| Tris(2-phenylpyridine) iridium complex (ortho- | 1 |
| metallation complex) | |
| Dichloroethane | 4,500 |

(B) Formation of Cathode and Organic Layer on First Substrate

First substrates 201 to 205 were prepared by using materials and processes shown in Table 2. The linear thermal expansion coefficient α and the maximum surface roughness Rmax of each first substrate 201 to 205 were measured. The results are shown in Table 2.

| | | α⁽¹⁾ | |
|---|---|---|---|
| | | (ppm/ | Rmax⁽²⁾ |
| No. | First Substrate | ° C.) | (nm) |
| 201 | 50-μm-thick polyimide sheets | 10 | 2 |
| | UPILEX 50S⁽³⁾ were adhered to | | |
| | both surfaces of 30-μm-thick | | |
| | aluminum sheet to form PI/Al/PI. | | |
| | Ultraviolet-curing resin liquid | | |
| | prepared by adding 10% by mass | | |
| | of Irgacure 651⁽⁴⁾ to Aronix | | |
| | M-450⁽⁵⁾ was applied to PI/Al/PI | | |
| | sheet surface by bar coater to | | |
| | dry thickness of 3 μm. Applied | | |
| | liquid was irradiated with 100-W, | | |
| | high-pressure mercury lamp from | | |
| | height of 5 cm for 5 minutes to | | |
| | prepare first substrate of | | |
| | UV/PI/Al/PI. | | |
| 202 | 50-μm-thick polyimide sheets | 10 | 3 |
| | UPILEX 50S⁽³⁾ were adhered to | | |
| | both surfaces of 30-μm-thick | | |
| | aluminum sheet to form PI/Al/PI. | | |
| | Thermosetting resin liquid | | |
| | EPX-49-10⁽⁶⁾ was applied to | | |
| | PI/Al/PI sheet surface by bar | | |
| | coater to dry thickness of | | |
| | 1 μm. Applied liquid was | | |
| | heated at 120° C. for 30 minutes | | |
| | to prepare first substrate of | | |
| | TH/PI/Al/PI. | | |
| 203 | 50-μm-thick polyimide sheets | 3 | 7 |
| | UPILEX 50S⁽³⁾ were adhered to | | |
| | both surfaces of 30-μm-thick | | |
| | aluminum sheet to form PI/Al/PI. | | |
| | 50-nm-thick silicon nitride | | |
| | film was formed on PI/Al/PI | | |
| | sheet surface by sputtering to | | |
| | prepare first substrate of | | |
| | Si₃N₄/PI/Al/PI. | | |
| 204 | 0.7-mm-thick white glass plate | 4 | 0.5 |
| 205 | 0.7-mm-thick quartz glass plate | 0.8 | 0.5 |

Note:
⁽¹⁾Linear thermal expansion coefficient measured by TMA method at a heating rate of 10° C./min.
⁽²⁾Rmax according to JIS B 0601-1982.
⁽³⁾UPILEX 50S: Trade name available from Ube Industries, Ltd.
⁽⁴⁾Irgacure 651: Trade name available from Chiba Specialty Chemicals Corporation.
⁽⁵⁾Aronix M-450: Trade name available from Toagosei Co., Ltd.
⁽⁶⁾EPX-49-10: Trade name available from Asahi Denka Co., Ltd.

A 250-nm-thick aluminum layer was formed as a cathode on each of the first substrates 201 to 205 by vapor deposition, and connected to an aluminum lead wire. An organic electron-transporting material represented by the following formula (1):

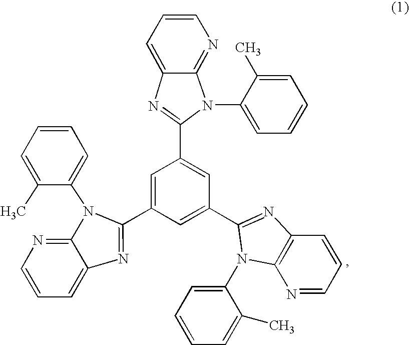

and LiF were vapor-deposited onto the aluminum layer (cathode) of each first substrate 201 to 205 to form a 36-nm-thick, electron-transporting organic layer. Their vapor deposition rates were controlled such that a ratio of LiF to the electron-transporting material in the resultant layer was 10%by mass.

(C) Formation of Organic Layer by Transfer Method

The light-emitting organic layer of the transfer material was superposed on the electron-transporting organic layer of the first substrate in each combination shown in Table 4. They were passed at a speed of 0.1 m/minute between a couple of heating rollers at a nip pressure of 0.3 MPa and a temperature of 160° C., to conduct a heating treatment and a pressing treatment simultaneously. The support was then peeled from the organic layer, so that the light-emitting organic layer was transferred onto the electron-transporting organic layer on the first substrate.

(D) Formation of Anode and Organic Layer on Second Substrate

A white glass plate of 0.5 mm×2.5 cm×2.5 cm having a linear thermal expansion coefficient α of 4 ppm/° C. (measured by a TMA method at a heating rate of 10° C./min) and a maximum surface roughness Rmax of 0.5 nm according to JIS B 0601-1982 was placed in a vacuum chamber, and a 0.2-μm-thick, transparent ITO thin-film electrode was formed on the white glass plate by DC magnetron sputtering using an ITO target containing 10% by mass of SnO₂ at an indium/tin molar ratio of 95/5, under the conditions that the white glass plate was at 250° C., and that an oxygen pressure was 1×10⁻³ Pa. The transparent ITO electrode of the resultant laminate had a surface resistance of 10 Ω/square. An aluminum lead wire was connected to the transparent ITO electrode. The white glass plate provided with the transparent ITO electrode was washed with isopropyl alcohol (IPA) and then subjected to an oxygen plasma treatment. The treated surface of the transparent ITO electrode was spin-coated with an aqueous dispersion of polyethylenedioxythiophene and polystyrene sulfonate (solid content: 1.3% by mass, Baytron P (trade name) available from BAYER AG), and vacuum-dried at 150° C. for 2 hours to form a hole-transporting organic layer having a thickness of 100 nm.

(E) Production of Organic EL Device

The hole-transporting organic layer formed on the second substrate was superposed on the light-emitting organic layer formed on each first substrate, and passed at a speed of 0.1 m/minute between a couple of heating rollers at a nip pressure of 0.3 MPa and a temperature of 160° C., to produce each organic EL device.

(F) Evaluation

The transferability of the light-emitting organic layer from each transfer material prepared in “(A) Preparation of transfer material” to each electron-transporting organic layer on the first substrate prepared in “(B) Formation of cathode and organic layer on first substrate” was evaluated by observing the surface of the transferred light-emitting organic layer by a fluorescence microscope in an area of 4 mm². The evaluation standards of the transferability are given below. The results are shown in Table 4.

Excellent: Transfer ratio was 95% or more,

Good: Transfer ratio was at least 80% and less than 95%, and

Poor: Transfer ratio was less than 80%.

The laminatability of each organic EL device produced in “(E) Production of organic EL device” was evaluated by applying DC voltage to each organic EL device by Source-Measure Unit 2400 available from Keithley Instruments, Inc. to cause light emission at a surface luminance of 200 Cd/m², and counting the number of defects per 1 mm² with a microscope. The evaluation standards of the laminatability are given below. The results are shown in Table 4.

Excellent: The number of defects was 5 or less,

Good: The number of defects was 6 to 20, and

Poor: The number of defects was 21 or more.

### Comparative Examples 1 and 2

Transfer materials of Comparative Examples 1 and 2 were prepared in the same manner as in Examples 1 to 8 except for using each of first substrates 206 and 207 prepared by using materials and processes shown in Table 3. Each organic EL device of Comparative Examples 1 and 2 was further produced by using each transfer material in the same manner as in Examples 1 to 8. The transferability of each light-emitting organic layer and the laminatability of each organic EL device were evaluated in the same manner as in Examples 1 to 8. The results are shown in Table 4.

### Reference Example 1

A transfer material of Reference Example 1 was prepared in the same manner as in Examples 1 to 8 except for using a first substrate 208 prepared by using materials and processes shown in Table 3. An organic EL device of Reference Example 1 was further produced by using the above transfer material in the same manner as in Examples 1 to 8. The transferability of the light-emitting organic layer and the laminatability of the organic EL device were evaluated in the same manner as in Examples 1 to 8. The results are shown in Table 4.

TABLE 3

| | | α⁽¹⁾ | |
|---|---|---|---|
| | | (ppm/ | Rmax⁽²⁾ |
| No. | First Substrate | ° C.) | (nm) |
| 206 | 50-μm-thick polyimide sheets | 10 | 250 |
| | UPILEX 50S⁽³⁾ were adhered to | | |
| | both surfaces of 30-μm-thick | | |
| | aluminum sheet to prepare first | | |
| | substrate of PI/Al/PI. | | |
| 207 | 50-μm-thick polyethylene | 55 | 40 |
| | terephthalate (PET) sheets | | |
| | Lumirror T-60⁽⁴⁾ were adhered to | | |
| | both surfaces of 30-μm-thick | | |
| | aluminum sheet to prepare first | | |
| | substrate of PET/Al/PET. | | |
| 208 | 50-μm-thick PET sheets Lumirror | 54 | 3 |
| | T-60⁽⁴⁾ were adhered to both | | |
| | surfaces of 30-μm-thick | | |
| | aluminum sheet to form PET/Al/PET. | | |
| | Ultraviolet-curing resin liquid | | |
| | prepared by adding 10% by mass of | | |
| | Irgacure 651⁽⁵⁾ to Aronix M-450⁽⁶⁾ | | |
| | was applied to PET/Al/PET sheet | | |
| | surface by bar coater to dry | | |
| | thickness of 3 μm. Applied liquid | | |
| | was irradiated with 100-W, high- | | |
| | pressure mercury lamp from height of | | |
| | 5 cm for 5 minutes to prepare first | | |
| | substrate of UV/PET/Al/PET. | | |

Note:
⁽¹⁾Linear thermal expansion coefficient measured by TMA method at a heating rate of 10° C./min.
⁽²⁾Rmax according to JIS B 0601-1982.
⁽³⁾UPILEX 50S: Trade name available from Ube Industries, Ltd.
⁽⁴⁾Lumirror T-60: Trade name available from Toray Industries, Inc.
⁽⁵⁾Irgacure 651: Trade name available from Chiba Specialty Chemicals Corporation.
⁽⁶⁾Aronix M-450: Trade name available from Toagosei Co., Ltd.

TABLE 4

| | | | | | | |
|---|---|---|---|---|---|---|
| No. | Example 1 | Example 2 | Example 3 | Example 4 | Example 5 | Example 6 |

Transfer Material

| | | | | | | |
|---|---|---|---|---|---|---|
| No. | 101 | 102 | 103 | 102 | 101 | 102 |
| Thickness of Organic | 15 | 40 | 80 | 40 | 15 | 40 |
| Layer (nm) | | | | | | |
| First Substrate | | | | | | |
| No. | 201 | 201 | 201 | 202 | 203 | 203 |
| Rmax (nm) | 2 | 2 | 2 | 3 | 7 | 7 |
| α⁽¹⁾ (ppm/° C.) | 10 | 10 | 10 | 10 | 3 | 3 |
| Structure | UV/PI/Al/PI | UV/PI/Al/PI | UV/PI/Al/PI | TH/PI/Al/PI | Si₃N₄/PI/Al/PI | Si₃N₄/PI/Al/PI |
| Rmax Ratio⁽²⁾ | 13/100 | 5/100 | 3/100 | 8/100 | 47/100 | 18/100 |
| Second Substrate | | | | | | |
| Rmax (nm) | 0.5 | 0.5 | 0.5 | 0.5 | 0.5 | 0.5 |
| α⁽¹⁾ (ppm/° C.) | 4 | 4 | 4 | 4 | 4 | 4 |
| Structure | White Glass | White Glass | White Glass | White Glass | White Glass | White Glass |
| Rmax Ratio⁽³⁾ | 3.3/100 | 13/100 | 0.6/100 | 1.3/100 | 3.3/100 | 1.3/100 |
| Transferability | Excellent | Excellent | Excellent | Excellent | Good | Excellent |
| Laminatability | Excellent | Excellent | Excellent | Excellent | Excellent | Excellent |

| | | | Comparative | Comparative | Reference |
|---|---|---|---|---|---|
| No. | Example 7 | Example 8 | Example 1 | Example 2 | Example 1 |
| Transfer Material | | | | | |
| No. | 102 | 102 | 102 | 102 | 102 |
| Thickness of Organic | 40 | 40 | 40 | 40 | 40 |
| Layer (nm) | | | | | |
| First Substrate | | | | | |
| No. | 204 | 205 | 206 | 207 | 208 |
| Rmax (nm) | 0.5 | 0.5 | 250 | 40 | 3 |
| α⁽¹⁾ (ppm/° C.) | 4 | 0.8 | 10 | 55 | 54 |
| Structure | White Glass | Quartz Glass | PI/Al/PI | PET/Al/PET | UV/PET/Al/PET |
| Rmax Ratio⁽²⁾ | 1.3/100 | 1.3/100 | 625/100 | 100/100 | 7.5/100 |
| Second Substrate | | | | | |
| Rmax (nm) | 0.5 | 0.5 | 0.5 | 0.5 | 0.5 |
| α⁽¹⁾ (ppm/° C.) | 4 | 4 | 4 | 4 | 4 |
| Structure | White Glass | White Glass | White Glass | White Glass | White Glass |
| Rmax Ratio⁽³⁾ | 1.3/100 | 1.3/100 | 3.3/100 | 13/100 | 13/100 |
| Transferability | Excellent | Excellent | Poor | Poor | Excellent |
| Laminatability | Excellent | Excellent | Good | Poor | Good |

Note
⁽¹⁾Linear thermal expansion coefficient (ppm/° C.).
⁽²⁾(Rmax of first substrate)/(thickness of transferred organic layer).
⁽³⁾(Rmax of second substrate)/(thickness of transferred organic layer)

were excellent in transferability and laminatability. In contrast, the organic EL devices of Comparative Examples 1 and 2 exhibited poor transferability and laminatability, because the ratio of (Rmax of first substrate)/(thickness of transferred organic layer) was more than 50. The organic EL device of Reference Example 1 exhibited relatively poor laminatability, because the first substrate had a linear thermal expansion coefficient α of more than 20 ppm/° C.

### EXAMPLES 9 TO 16

Organic EL devices of Examples 9 to 16 were produced in the same manner as in Examples 1 to 8, except that a hole-transporting organic layer having a thickness of 40 nm was formed by mixing a high-molecular compound PTPDES represented by the following formula (2):

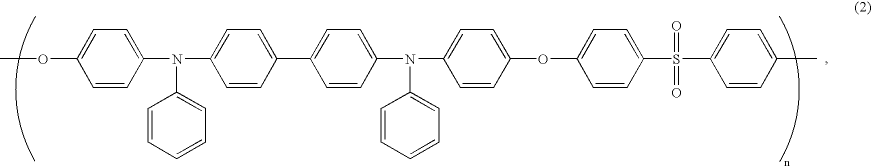

an additive TBPA represented by the following formula (3):

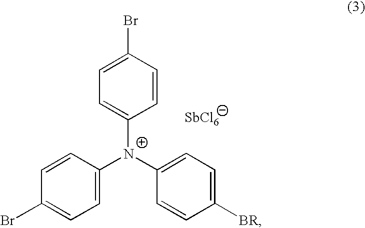

and dichloroethane at a mass ratio of PTPDES/TBPA/dichloroethane=40/10/3500 to obtain a coating liquid; applying the coating liquid to the anode of the second substrate by an extrusion coater; and drying the applied coating liquid at room temperature.

The transferability of each light-emitting organic layer and the laminatability of each organic EL device were evaluated in the same manner as in Examples 1 to 8. The results are shown in Table 5.

### Comparative Examples 3 and 4

Organic EL devices of Comparative Examples 3 and 4 were produced in the same manner as in Comparative Examples 1 and 2, except that a hole-transporting organic layer was formed on the anode of the second substrate in the same manner as in Examples 9 to 16. The transferability of each light-emitting organic layer and the laminatability of each organic EL device were evaluated in the same manner as in Examples 1 to 8. The results are shown in Table 5.

### Reference Example 2

An organic EL device of Reference Example 2 was produced in the same manner as in Reference Example 1 except that a hole-transporting organic layer was formed on the anode of the second substrate in the same manner as in Examples 9 to 16. The transferability of the light-emitting organic layer and the laminatability of the organic EL device were evaluated in the same manner as in Examples 1 to 8. The results are shown in Table 5.

TABLE 5

| | | | | | | |
|---|---|---|---|---|---|---|
| No. | Example 9 | Example 10 | Example 11 | Example 12 | Example 13 | Example 14 |

Transfer Material

| | | | | | | |
|---|---|---|---|---|---|---|
| No. | 101 | 102 | 103 | 102 | 101 | 102 |
| Thickness of Organic | 15 | 40 | 80 | 40 | 15 | 40 |
| Layer (nm) | | | | | | |
| First Substrate | | | | | | |
| No. | 201 | 201 | 201 | 202 | 203 | 203 |
| Rmax (nm) | 2 | 2 | 2 | 3 | 7 | 7 |
| α⁽¹⁾ (ppm/° C.) | 10 | 10 | 10 | 10 | 3 | 3 |
| Structure | UV/PI/Al/PI | UV/PI/Al/PI | UV/PI/Al/PI | TH/PI/Al/PI | Si₃N₄/PI/Al/PI | Si₃N₄/PI/Al/PI |
| Rmax Ratio⁽²⁾ | 13/100 | 5/100 | 3/100 | 8/100 | 47/100 | 18/100 |
| Second Substrate | | | | | | |
| Rmax (nm) | 0.5 | 0.5 | 0.5 | 0.5 | 0.5 | 0.5 |
| α⁽¹⁾ (ppm/° C.) | 4 | 4 | 4 | 4 | 4 | 4 |
| Structure | White Glass | White Glass | White Glass | White Glass | White Glass | White Glass |
| Rmax Ratio⁽³⁾ | 3.3/100 | 13/100 | 0.6/100 | 1.3/100 | 3.3/100 | 1.3/100 |
| Transferability | Excellent | Excellent | Excellent | Excellent | Good | Excellent |
| Laminatability | Excellent | Excellent | Excellent | Excellent | Excellent | Excellent |

| | | | Comparative | Comparative | Reference |
|---|---|---|---|---|---|
| No. | Example 15 | Example 16 | Example 3 | Example 4 | Example 2 |
| Transfer Material | | | | | |
| No. | 102 | 102 | 102 | 102 | 102 |
| Thickness of Organic | 40 | 40 | 40 | 40 | 40 |
| Layer (nm) | | | | | |
| First Substrate | | | | | |
| No. | 204 | 205 | 206 | 207 | 208 |
| Rmax (nm) | 0.5 | 0.5 | 250 | 40 | 3 |
| α⁽¹⁾ (ppm/° C.) | 4 | 0.8 | 10 | 55 | 54 |
| Structure | White Glass | Quartz Glass | PI/Al/PI | PET/Al/PET | UV/PET/Al/PET |
| Rmax Ratio⁽²⁾ | 1.3/100 | 1.3/100 | 625/100 | 100/100 | 7.5/100 |
| Second Substrate | | | | | |
| Rmax (nm) | 0.5 | 0.5 | 0.5 | 0.5 | 0.5 |
| α⁽¹⁾ (ppm/° C.) | 4 | 4 | 4 | 4 | 4 |
| Structure | White Glass | White Glass | White Glass | White Glass | White Glass |
| Rmax Ratio⁽³⁾ | 1.3/100 | 1.3/100 | 3.3/100 | 13/100 | 13/100 |
| Transferability | Excellent | Excellent | Poor | Poor | Excellent |
| Laminatability | Excellent | Excellent | Good | Poor | Good |

Note
⁽¹⁾Linear thermal expansion coefficient (ppm/° C.).
⁽²⁾(Rmax of first substrate)/(thickness of transferred organic layer).
⁽³⁾(Rmax of second substrate)/(thickness of transferred organic layer)

As shown in Table 5, the organic EL devices of Examples 9 to 16 were excellent in transferability and laminatability. In contrast, the organic EL devices of Comparative Examples 3 and 4 exhibited poor transferability and laminatability, because the ratio of (Rmax of first substrate)/(thickness of transferred organic layer) was more than 50. The organic EL device of Reference Example 2 exhibited relatively poor laminatability, because the first substrate had a linear thermal expansion coefficient α of more than 20 ppm/° C.

### EXAMPLES 17 TO 25

Organic EL devices of Examples 17 to 25 were produced in the same manner as in Examples 1 to 8 except that second substrates of 2.5 cm×2.5 cm shown in Table 6 were used in combination with the first substrates 201 to 208 prepared in Examples 1 to 8 and the transfer material 102 used in Example 2 having the 40-nm-thick light-emitting layer as shown in Table 8. The transferability of each light-emitting organic layer and the laminatability of each organic EL device were evaluated in the same manner as in Examples 1 to 8. The results are shown in Table 8.

TABLE 6

| | | α⁽¹⁾ | |
|---|---|---|---|
| | | (ppm/ | Rmax⁽²⁾ |
| No. | Second Substrate | ° C.) | (nm) |
| 301 | Ultraviolet-curing resin liquid | 12 | 2 |
| | prepared by adding 10% by mass | | |
| | of Irgacure 651⁽³⁾ to Aronix | | |
| | M-450⁽⁴⁾ was applied to surface | | |
| | of 50-μm-thick rigid polyvinyl | | |
| | chloride sheet by bar coater to | | |
| | dry thickness of 3 μm. Applied | | |
| | liquid was irradiated with 100-W, | | |
| | high-pressure mercury lamp from | | |
| | height of 5 cm for 5 minutes to | | |
| | prepare second substrate of | | |
| | UV/PVC. | | |
| 302 | Thermosetting resin liquid | 15 | 3 |
| | EPX-49-10⁽⁵⁾ was applied to | | |
| | surface of 50-μm-thick rigid | | |
| | polyvinyl chloride sheet by bar | | |
| | coater to dry thickness of 1 μm. | | |
| | Applied liquid was heated at | | |
| | 120° C. for 30 minutes to prepare | | |
| | second substrate of TH/PVC. | | |
| 303 | 50-nm-thick silicon nitride film | 10 | 7 |
| | was formed on surface of 50-μm- | | |
| | thick rigid polyvinyl chloride | | |
| | sheet by sputtering to prepare | | |
| | second substrate of Si₃N₄/PVC. | | |
| 304 | 0.7-mm-thick white glass plate | 4 | 0.5 |
| 305 | 0.7-mm-thick quartz glass plate | 0.8 | 0.5 |
| 306 | 50-μm-thick rigid polyvinyl | 12 | 205 |
| | chloride sheet (PVC) | | |
| 307 | 50-μm-thick PET sheet Lumirror | 65 | 40 |
| | T-60⁽⁶⁾. | | |
| 308 | Ultraviolet-curing resin liquid | 64 | 3 |
| | prepared by adding 10% by mass | | |
| | of Irgacure 651⁽²⁾ to Aronix | | |
| | M-450⁽³⁾ was applied to 50-μm- | | |
| | thick PET sheet Lumirror T- | | |
| | 60⁽⁶⁾ by bar coater to dry | | |
| | thickness of 3 μm. Applied | | |
| | liquid was irradiated with 100-W, | | |
| | high-pressure mercury lamp from | | |
| | height of 5 cm for 5 minutes to | | |
| | prepare second substrate of | | |
| | UV/PET. | | |

Note:
⁽¹⁾Linear thermal expansion coefficient measured by TMA method at a heating rate of 10° C./min.
⁽²⁾Rmax according to JIS B 0601-1982.
⁽³⁾Irgacure 651: Trade name available from Chiba Specialty Chemicals Corporation.
⁽⁴⁾Aronix M-450: Trade name available from Toagosei Co., Ltd.
⁽⁵⁾EPX-49-10: Trade name available from Asahi Denka Co., Ltd.
⁽⁶⁾Lumirror T-60: Trade name available from Toray Industries, Inc.

### Comparative Examples 5 and 6

Organic EL devices of Comparative Examples 5 and 6 were produced in the same manner as in Examples 17 to 25 except that second substrates shown in Table 7 were used with the first substrates 201, 206, and 207 used in Example 1 and Comparative Examples 1 and 2 in combination as shown in Table 8. The transferability of each light-emitting organic layer and the laminatability of each organic EL device were evaluated in the same manner as in Examples 1 to 8. The results are shown in Table 8.

### Reference Examples 3 to 6

Organic EL devices of Reference Examples 3 to 6 were produced in the same manner as in Examples 17 to 25 except that second substrates shown in Table 7 were used with the first substrates 201 and 208 used in Example 1 and Reference Examples 1 and 2 in combination as shown in Table 8. The transferability of each light-emitting organic layer and the laminatability of each organic EL device were evaluated in the same manner as in Examples 1 to 8. The results are shown in Table 8.

TABLE 7

| | | α⁽¹⁾ | |
|---|---|---|---|
| | | (ppm/ | Rmax⁽²⁾ |
| No. | Second Substrate | ° C.) | (nm) |
| 306 | 50-μm-thick rigid polyvinyl | 12 | 205 |
| | chloride sheet (PVC) | | |
| 307 | 50-μm-thick PET sheet Lumirror | 65 | 40 |
| | T-60⁽³⁾ | | |
| 308 | Ultraviolet-curing resin liquid | 64 | 3 |
| | prepared by adding 10% by mass of | | |
| | Irgacure 651⁽⁴⁾ to Aronix M-450⁽⁵⁾ | | |
| | was applied to 50-μm-thick PET | | |
| | sheet Lumirror T-60⁽³⁾ by bar | | |
| | coater to dry thickness of 3 μm. | | |
| | Applied liquid was irradiated with | | |
| | 100-W, high-pressure mercury lamp | | |
| | from height of 5 cm for 5 minutes | | |
| | to prepare second substrate of | | |
| | UV/PET. | | |

Note:
⁽¹⁾Linear thermal expansion coefficient measured by TMA method at a heating rate of 10° C./min.
⁽²⁾Rmax according to JIS B 0601-1982.
⁽³⁾Lumirror T-60: Trade name available from Toray Industries, Inc.
⁽⁴⁾Irgacure 651: Trade name available from Chiba Specialty Chemicals Corporation.
⁽⁵⁾Aronix M-450: Trade name available from Toagosei Co., Ltd.

TABLE 8

| | | | | | | | | |
|---|---|---|---|---|---|---|---|---|
| No. | Example 17 | Example 18 | Example 19 | Example 20 | Example 21 | Example 22 | Example 23 | Example 24 |

Transfer Material

| | | | | | | | | |
|---|---|---|---|---|---|---|---|---|
| No. | 102 | 102 | 102 | 102 | 102 | 102 | 102 | 102 |
| Thickness of Organic | 40 | 40 | 40 | 40 | 40 | 40 | 40 | 40 |
| Layer (nm) | | | | | | | | |
| First Substrate | | | | | | | | |
| No. | 201 | 201 | 201 | 201 | 201 | 202 | 203 | 204 |
| Rmax (nm) | 2 | 2 | 2 | 2 | 2 | 3 | 7 | 0.5 |
| α⁽¹⁾ (ppm/° C.) | 10 | 10 | 10 | 10 | 10 | 10 | 3 | 4 |
| Structure | UV/PI/Al/PI | UV/PI/Al/PI | UV/PI/Al/PI | UV/PI/Al/PI | UV/PI/Al/PI | TH/PI/Al/PI | Si₃N₄/PI/Al/PI | White Glass |
| Rmax Ratio⁽²⁾ | 5/100 | 5/100 | 5/100 | 5/100 | 5/100 | 7.5/100 | 18/100 | 1.3/100 |
| Second Substrate | | | | | | | | |
| No. | 301 | 302 | 303 | 304 | 305 | 301 | 301 | 304 |
| Rmax (nm) | 2 | 3 | 7 | 0.5 | 0.5 | 2 | 2 | 0.5 |
| α⁽¹⁾ (ppm/° C.) | 12 | 15 | 10 | 4 | 0.8 | 12 | 12 | 4 |
| Structure | UV/PVC | TH/PVC | Si₃N₄/PVC | White Glass | Quartz Glass | UV/PVC | UV/PVC | White Glass |
| Rmax Ratio⁽³⁾ | 5/100 | 7.5/100 | 18/100 | 1.3/100 | 1.3/100 | 5/100 | 5/100 | 1.3/100 |
| Transferability | Excellent | Excellent | Excellent | Excellent | Excellent | Excellent | Excellent | Excellent |
| Laminatability | Excellent | Excellent | Excellent | Excellent | Excellent | Excellent | Excellent | Excellent |

| | | Comparative | Comparative | Reference | Reference | Reference | Reference |
|---|---|---|---|---|---|---|---|
| No. | Example 25 | Example 5 | Example 6 | Example 3 | Example 4 | Example 5 | Example 6 |
| Transfer Material | | | | | | | |
| No. | 102 | 102 | 102 | 102 | 102 | 102 | 102 |
| Thickness of Organic | 40 | 40 | 40 | 40 | 40 | 40 | 40 |
| Layer (nm) | | | | | | | |
| First Substrate | | | | | | | |
| No. | 205 | 206 | 207 | 201 | 201 | 201 | 208 |
| Rmax (nm) | 0.5 | 250 | 40 | 2 | 2 | 2 | 3 |
| α⁽¹⁾ (ppm/° C.) | 0.8 | 10 | 55 | 10 | 10 | 10 | 54 |
| Structure | Quartz Glass | PI/Al/PI | PET/Al/PET | UV/PI/Al/PI | UV/PI/Al/PI | UV/PI/Al/PI | UV/PET/Al/PET |
| Rmax Ratio⁽²⁾ | 1.3/100 | 625/100 | 100/100 | 5/100 | 5/100 | 5/100 | 7.5/100 |
| Second Substrate | | | | | | | |
| No. | 305 | 306 | 307 | 306 | 307 | 308 | 308 |
| Rmax (nm) | 0.5 | 205 | 40 | 205 | 40 | 3 | 3 |
| α⁽¹⁾ (ppm/° C.) | 0.8 | 12 | 65 | 12 | 65 | 64 | 64 |
| Structure | Quartz Glass | PVC | PET | PVC | PET | UV/PET | UV/PET |
| Rmax Ratio⁽³⁾ | 1.3/100 | 513/100 | 100/100 | 513/100 | 100/100 | 7.5/100 | 7.5/100 |
| Transferability | Excellent | Poor | Poor | Excellent | Excellent | Excellent | Excellent |
| Laminatability | Excellent | Good | No lamination | Good | Poor | Poor | No lamination |
| | | | at all | | | | at all |

Note
⁽¹⁾Linear thermal expansion coefficient (ppm/° C.).
⁽²⁾(Rmax of first substrate)/(thickness of transferred organic layer).
⁽³⁾(Rmax of second substrate)/(thickness of transferred organic layer)

As shown in Table 8, the organic EL devices of Examples 17 to 25 were excellent in transferability and laminatability. In contrast, the organic EL devices of Comparative Examples 5 and 6 exhibited poor transferability and laminatability, because the ratio of (Rmax of first substrate)/(thickness of transferred organic layer) was more than 50. The organic EL devices in Reference Examples 3 to 6 were poor in laminatability, because the ratio of (Rmax of second substrate)/(thickness of transferred organic layer) was more than 50 in Reference Example 3; because the ratio of (Rmax of second substrate)/(thickness of transferred organic layer) was more than 50, and the second substrate had a linear thermal expansion coefficient α of more than 20 ppm/° C. in Reference Example 4; because the second substrate had a linear thermal expansion coefficient α of more than 20 ppm/° C. in Reference Example 5; and because the first and second substrates had a linear thermal expansion coefficient a of more than 20 ppm/° C. in Reference Example 6.

### EXAMPLES 26 TO 30

Organic EL devices of Examples 26 to 30 were produced in the same manner as in Examples 1 to 8, except that the transfer material 102 having the same 40-nm-thick light-emitting organic layer as in Example 2 was used, that the second substrates each having the same hole-transporting organic layer as in Examples 1 to 8 were used as the organic layer-carrying first substrates, and that the first substrates each having the same electron-transporting organic layer as in Examples 1 to 8 were used as the organic layer-carrying second substrates. The transferability of each light-emitting organic layer and the laminatability of each organic EL device were evaluated in the same manner as in Examples 1 to 8. The results are shown in Table 9.

### Reference Examples 7 to 9

Organic EL devices of Reference Examples 7 to 9 were produced in the same manner as in Comparative Examples 1 and 2, except that the transfer material 102 having the same 40-nm-thick light-emitting organic layer as in Example 2 was used, that the second substrates each having the same hole-transporting organic layer as in Comparative Examples 1 and 2 were used as the organic layer-carrying first substrates, and that the first substrates each having the same electron-transporting organic layer as in Comparative Examples 1 and 2 were used as the organic layer-carrying second substrates. The transferability of each light-emitting organic layer and the laminatability of each organic EL device were evaluated in the same manner as in Examples 1 to 8. The results are shown in Table 9.

TABLE 9

| | | | | |
|---|---|---|---|---|
| No. | Example 26 | Example 27 | Example 28 | Example 29 |

Transfer Material

| | | | | |
|---|---|---|---|---|
| No. | 102 | 102 | 102 | 102 |
| Thickness of Organic | 40 | 40 | 40 | 40 |
| Layer (nm) | | | | |
| First Substrate | | | | |
| Rmax (nm) | 0.5 | 0.5 | 0.5 | 0.5 |
| α⁽¹⁾ (ppm/° C.) | 4 | 4 | 4 | 4 |
| Structure | White Glass | White Glass | White Glass | White Glass |
| Rmax Ratio⁽²⁾ | 1.3/100 | 1.3/100 | 1.3/100 | 1.3/100 |
| Second Substrate | | | | |
| No. | 201 | 202 | 203 | 204 |
| Rmax (nm) | 2 | 3 | 7 | 0.5 |
| α⁽¹⁾ (ppm/° C.) | 10 | 10 | 3 | 4 |
| Structure | UV/PI/Al/PI | TH/PI/Al/PI | Si₃N₄/PI/Al/PI | White Glass |
| Rmax Ratio⁽³⁾ | 5/100 | 7.5/100 | 18/100 | 1.3/100 |
| Transferability | Excellent | Excellent | Excellent | Excellent |
| Laminatability | Excellent | Excellent | Excellent | Excellent |

| | | Reference | Reference | Reference |
|---|---|---|---|---|
| No. | Example 30 | Example 7 | Example 8 | Example 9 |
| Transfer Material | | | | |
| No. | 102 | 102 | 102 | 102 |
| Thickness of Organic | 40 | 40 | 40 | 40 |
| Layer (nm) | | | | |
| First Substrate | | | | |
| Rmax (nm) | 0.5 | 0.5 | 0.5 | 0.5 |
| α⁽¹⁾ (ppm/° C.) | 4 | 4 | 4 | 4 |
| Structure | White Glass | White Glass | White Glass | White Glass |
| Rmax Ratio⁽²⁾ | 1.3/100 | 1.3/100 | 1.3/100 | 1.3/100 |
| Second Substrate | | | | |
| No. | 205 | 206 | 207 | 208 |
| Rmax (nm) | 0.5 | 250 | 40 | 3 |
| α⁽¹⁾ (ppm/° C.) | 0.8 | 10 | 55 | 54 |
| Structure | Quartz Glass | PI/Al/PI | PET/Al/PET | UV/PET/Al/PET |
| Rmax Ratio⁽³⁾ | 1.3/100 | 625/100 | 100/100 | 7.5/100 |
| Transferability | Excellent | Excellent | Excellent | Excellent |
| Laminatability | Excellent | Good | Poor | Poor |

Note
⁽¹⁾Linear thermal expansion coefficient (ppm/° C.).
⁽²⁾(Rmax of first substrate)/(thickness of transferred organic layer).
⁽³⁾(Rmax of second substrate)/(thickness of transferred organic layer)

As shown in Table 9, the organic EL devices of Examples 26 to 30 were excellent in transferability and laminatability. The organic EL devices of Reference Examples 7 to 9 were poor in laminatability, because the ratio of (Rmax of second substrate)/(thickness of transferred organic layer) was more than 50 in Reference Example 7, and because the second substrate had a linear thermal expansion coefficient α of more than 20 ppm/° C. in Reference Examples 8 and 9.

### EXAMPLES 31 to 38

(A) Transfer Material

Transfer materials 104 and 105 were prepared in addition to the transfer material 102 of Example 2. The transfer material 104 was produced by applying a coating liquid containing 1-butanol, polyvinyl butyral (Mw=50,000, available from Aldrich Chemical Co.), and an electron-transporting compound represented by the following formula (4):

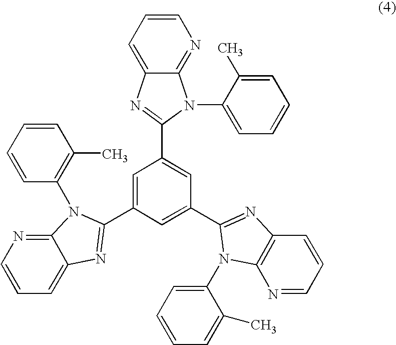

to one surface of a 188-μm-thick support made of polyether sulfone available from Sumitomo Bakelite Co., Ltd. using an extrusion coater, and vacuum-drying the applied coating liquid at 80° C. for 2 hours to form an electron-transporting organic layer having a thickness of 60 nm. The composition of the coating liquid for the electron-transporting organic layer is shown in Table 10.

TABLE 10

| Composition | Mass Ratio |
|---|---|
| Polyvinyl butyral (Mw = 50,000, available from | 10 |
| Aldrich Chemical Co.) | |
| Electron-transporting organic material represented | 20 |
| by formula (4) | |
| 1-Butanol | 3,500 |

The transfer material 105 was produced by applying the coating liquid used in Examples 9 to 16 to one surface of a 188-μm-thick support made of polyether sulfone available from Sumitomo Bakelite Co., Ltd. using an extrusion coater, and drying the applied coating liquid at room temperature to form a hole-transporting organic layer having a thickness of 40 nm.

(B) Formation of Cathode on First Substrate

An Al layer having a thickness of 250 nm was formed as a cathode on each of the same first substrates as in Examples 1 to 8 by a vapor deposition method. An aluminum lead wire was then connected to the cathode.

(C) Formation of Organic Layer by Transfer Method

The electron-transporting organic layer of the transfer material 104 was superposed on the cathode of each first substrate, and passed at a speed of 0.1 m/minute between a couple of heating rollers at a nip pressure of 0.3 MPa and a temperature of 160° C. in the same manner as in Examples 1 to 8, and the support was peeled from the transfer material 104, so that the electron-transporting organic layer was transferred onto the cathode on the first substrate.

The light-emitting organic layer of the transfer material 102 was then superposed on the electron-transporting organic layer transferred onto the first substrate via the cathode, and passed at a speed of 0.1 m/minute between a couple of heating rollers at a nip pressure of 0.3 MPa and a temperature of 160° C. in the same manner as in Examples 1 to 8, and the support was peeled from the transfer material 102, so that the light-emitting organic layer was transferred onto the electron-transporting organic layer on the first substrate.

Further, the hole-transporting organic layer of the transfer material 105 was superposed on the light-emitting organic layer transferred onto the first substrate via the cathode and the electron-transporting organic layer, and passed at a speed of 0.1 m/minute between a couple of heating rollers at a nip pressure of 0.3 MPa and a temperature of 160° C. in the same manner as in Examples 1 to 8, and the support was peeled from the transfer material 105, so that the hole-transporting organic layer was transferred onto the light-emitting organic layer on the first substrate.

(D) Formation of Anode on Second Substrate

A transparent 0.2-μm-thick ITO thin-film electrode was formed on a white glass plate of 0.5 mm×2.5 cm×2.5 cm having a linear thermal expansion coefficient α of 4 ppm/° C. and a maximum surface roughness Rmax of 0.5 nm according to JIS B 0601-1982 in the same manner as in Examples 1 to 8. The transparent ITO electrode had a surface resistance of 10 Ω/square. An aluminum lead wire was connected to the transparent ITO electrode. The glass plate provided with the transparent electrode was washed with isopropyl alcohol (IPA) and then subjected to an oxygen plasma treatment.

(E) Production of Organic EL Device

The hole-transporting organic layer formed on each first substrate was superposed on the anode formed on the second substrate, and passed at a speed of 0.1 m/minute between a couple of heating rollers at a nip pressure of 0.3 MPa and a temperature of 160° C., to produce each organic EL device of Examples 31 to 38.

(F) Evaluation

The transferability of each organic layer and the laminatability of each organic EL device were evaluated in the same manner as in Examples 1 to 8. The results are shown in Table 11.

### Comparative Examples 7 and 8

Organic EL devices of Comparative Examples 7 and 8 were produced in the same manner as in Examples 31 to 38 except for using the same first substrates 206, 207 as in Examples 1 and 2. The transferability of the organic layer and the laminatability of each organic EL device were evaluated in the same manner as in Examples 1 to 8. The results are shown in Table 11.

### Reference Example 10

An organic EL device of Reference Example 10 was produced in the same manner as in Examples 31 to 38 except for using the same first substrate 208 as in Reference Examples 1 and 2. The transferability of the organic layer and the laminatability of the organic EL device were evaluated in the same manner as in Examples 1 to 8. The results are shown in Table 11.

TABLE 11

| No. | Example 31 | Example 32 | Example 33 | Example 34 | Example 35 | Example 36 |
|---|---|---|---|---|---|---|
| Transfer Material 104 | 60 | 60 | 60 | 60 | 60 | 60 |
| Thickness of Organic | | | | | | |
| Layer (nm) | | | | | | |
| Transfer Material 102 | 40 | 40 | 40 | 40 | 40 | 40 |
| Thickness of Organic | | | | | | |
| Layer (nm) | | | | | | |
| Transfer Material 105 | 40 | 40 | 40 | 40 | 40 | 40 |
| Thickness of Organic | | | | | | |
| Layer (nm) | | | | | | |
| First Substrate | | | | | | |
| No. | 201 | 201 | 201 | 202 | 203 | 203 |
| Rmax (nm) | 2 | 2 | 2 | 3 | 7 | 7 |
| α⁽¹⁾ (ppm/° C.) | 10 | 10 | 10 | 10 | 3 | 3 |
| Structure | UV/PI/Al/PI | UV/PI/Al/PI | UV/PI/Al/PI | TH/PI/Al/PI | Si₃N₄/PI/Al/PI | Si₃N₄/PI/Al/PI |
| Rmax Ratio⁽²⁾ | | | | | | |
| Transfer material 104 | 3.3/100 | 3.3/100 | 3.3/100 | 5/100 | 12/100 | 12/100 |
| Transfer material 102 | 5/100 | 5/100 | 5/100 | 7.5/100 | 18/100 | 18/100 |
| Transfer material 105 | 5/100 | 5/100 | 5/100 | 7.5/100 | 18/100 | 18/100 |
| Second Substrate | | | | | | |
| Rmax (nm) | 0.5 | 0.5 | 0.5 | 0.5 | 0.5 | 0.5 |
| α⁽¹⁾ (ppm/° C.) | 4 | 4 | 4 | 4 | 4 | 4 |
| Structure | White Glass | White Glass | White Glass | White Glass | White Glass | White Glass |
| Rmax Ratio⁽³⁾ | 0.4/100 | 0.4/100 | 0.4/100 | 0.4/100 | 0.4/100 | 0.4/100 |
| Transferability | | | | | | |
| Transfer Material 104 | Excellent | Excellent | Excellent | Excellent | Excellent | Excellent |
| Transfer Material 102 | Excellent | Excellent | Excellent | Excellent | Excellent | Excellent |
| Transfer Material 105 | Excellent | Excellent | Excellent | Excellent | Excellent | Excellent |
| Laminatability | Excellent | Excellent | Excellent | Excellent | Excellent | Excellent |

| | | | Comparative | Comparative | Reference |
|---|---|---|---|---|---|
| No. | Example 37 | Example 38 | Example 7 | Example 8 | Example 10 |
| Transfer Material 104 | 60 | 60 | 60 | 60 | 60 |
| Thickness of Organic | | | | | |
| Layer (nm) | | | | | |
| Transfer Material 102 | 40 | 40 | 40 | 40 | 40 |
| Thickness of Organic | | | | | |
| Layer (nm) | | | | | |
| Transfer Material 105 | 40 | 40 | 40 | 40 | 40 |
| Thickness of Organic | | | | | |
| Layer (nm) | | | | | |
| First Substrate | | | | | |
| No. | 204 | 205 | 206 | 207 | 208 |
| Rmax (nm) | 0.5 | 0.5 | 250 | 40 | 3 |
| α⁽¹⁾ (ppm/° C.) | 4 | 0.8 | 10 | 55 | 54 |
| Structure | White Glass | Quartz Glass | PI/Al/PI | PET/Al/PET | UV/PET/Al/PET |
| Rmax Ratio⁽²⁾ | | | | | |
| Transfer material 104 | 0.8/100 | 0.8/100 | 417/100 | 67/100 | 5/100 |
| Transfer material 102 | 1.3/100 | 1.3/100 | 625/100 | 100/100 | 7.5/100 |
| Transfer material 105 | 1.3/100 | 1.3/100 | 625/100 | 100/100 | 7.5/100 |
| Second Substrate | | | | | |
| Rmax (nm) | 0.5 | 0.5 | 0.5 | 0.5 | 0.5 |
| α⁽¹⁾ (ppm/° C.) | 4 | 4 | 4 | 4 | 4 |
| Structure | White Glass | White Glass | White Glass | White Glass | White Glass |
| Rmax Ratio⁽³⁾ | 0.4/100 | 0.4/100 | 0.4/100 | 0.4/100 | 0.4/100 |
| Transferability | | | | | |
| Transfer Material 104 | Excellent | Excellent | Poor | Poor | Excellent |
| Transfer Material 102 | Excellent | Excellent | Poor | Poor | Excellent |
| Transfer Material 105 | Excellent | Excellent | Poor | Poor | Excellent |
| Laminatability | Excellent | Excellent | Good | Poor | Good |

Note
⁽¹⁾Linear thermal expansion coefficient (ppm/° C.).
⁽²⁾(Rmax of first substrate)/(thickness of transferred organic layer).
⁽³⁾(Rmax of second substrate)/(thickness of transferred organic layer)

As shown in Table 11, the organic EL devices of Examples 31 to 38 were excellent in transferability and laminatability. In contrast, the organic EL devices of Comparative Examples 7 and 8 exhibited poor transferability and laminatability, because the ratio of (Rmax of first substrate)/(thickness of transferred organic layer) was more than 50. The organic EL device of Reference Example 10 exhibited relatively poor laminatability, because the first substrate had a linear thermal expansion coefficient a of more than 20 ppm/° C.

### EXAMPLES 39 to 43

(A) Preparation of Transfer Materials 102, 104, and 105

The transfer materials 102, 104, and 105 were used in the same manner as in Examples 31 to 38.

(B) Formation of Anode on First Substrate

Each second substrate 301 to 305 used in Examples 17 to 22 was used as a first substrate, and a 0.2-μm-thick, transparent ITO thin-film electrode was formed on the first substrate in the same manner as in Examples 1 to 8. The transparent ITO electrode had a surface resistance of 10 Ω/square. An aluminum lead wire was connected to the transparent ITO electrode. The first substrate provided with the transparent electrode was washed with isopropyl alcohol (IPA) and then subjected to an oxygen plasma treatment.

(C) Formation of Organic Layer by Transfer Method

The hole-transporting organic layer of the transfer material 105 was superposed on the anode of each first substrate, and passed at a speed of 0.1 m/minute between a couple of heating rollers at a nip pressure of 0.3 MPa and a temperature of 160° C. in the same manner as in Examples 1 to 8, and the support was peeled from the transfer material 105 to transfer the hole-transporting organic layer onto the anode on the first substrate. The light-emitting organic layer of the transfer material 102 was then superposed on the hole-transporting organic layer transferred onto the first substrate via the electrode, and passed at a speed of 0.1 m/minute between a couple of heating rollers at a nip pressure of 0.3 MPa and a temperature of 160° C. in the same manner as in Examples 1 to 8, and the support was peeled from the transfer material 102 to transfer the light-emitting organic layer onto the hole-transporting organic layer on the first substrate. Further, the electron-transporting organic layer of the transfer material 104 was superposed on the light-emitting organic layer transferred onto the first substrate via the electrode and the hole-transporting organic layer, and passed at a speed of 0.1 m/minute between a couple of heating rollers at a nip pressure of 0.3 MPa and a temperature of 160° C. in the same manner as in Examples 1 to 8, and the support was peeled from the transfer material 104 to transfer the electron-transporting organic layer onto the light-emitting organic layer on the first substrate.

(D) Production of Organic EL Device

A 250-nm-thick Al layer was formed as a cathode on the electron-transporting organic layer on the first substrate by a vapor deposition method. An aluminum lead wire was then connected to the cathode to produce the organic EL devices of Examples 39 to 43.

(E) Evaluation

The transferability of each organic layer and the laminatability of each organic EL device were evaluated in the same manner as in Examples 1 to 8. The results are shown in Table 12.

### Comparative Examples 9 and 10

Organic EL devices of Comparative Examples 9 and 10 were produced in the same manner as in Examples 39 to 43 except for using each second substrate 306, 307 of Comparative Examples 5 and 6 as a first substrate. The transferability of each organic layer from the transfer material was evaluated in the same manner as in Examples 1 to 8. The results are shown in Table 12.

TABLE 12

| | | | | | | Comparative | Comparative |
|---|---|---|---|---|---|---|---|
| No. | Example 39 | Example 40 | Example 41 | Example 42 | Example 43 | Example 9 | Example 10 |
| Transfer Material 105 | 40 | 40 | 40 | 40 | 40 | 40 | 40 |
| Thickness of Organic | | | | | | | |
| Layer (nm) | | | | | | | |
| Transfer Material 104 | 60 | 60 | 60 | 60 | 60 | 60 | 60 |
| Thickness of Organic | | | | | | | |
| Layer (nm) | | | | | | | |
| Transfer Material 102 | 40 | 40 | 40 | 40 | 40 | 40 | 40 |
| Thickness of Organic | | | | | | | |
| Layer (nm) | | | | | | | |
| First Substrate | | | | | | | |
| No. | 301 | 302 | 303 | 304 | 305 | 306 | 307 |
| Rmax (nm) | 2 | 3 | 7 | 0.5 | 0.5 | 205 | 40 |
| α⁽¹⁾ (ppm/° C.) | 12 | 15 | 10 | 4 | 0.8 | 12 | 65 |
| Structure | UV/PVC | TH/PVC | Si₃N₄/PVC | White Glass | Quartz Glass | PVC | PET |
| Rmax Ratio⁽²⁾ | | | | | | | |
| Transfer Material 105 | 5/100 | 7.5/100 | 18/100 | 1.3/100 | 1.3/100 | 513/100 | 100/100 |
| Transfer Material 104 | 3/100 | 5/100 | 12/100 | 0.8/100 | 0.8/100 | 342/100 | 67/100 |
| Transfer Material 102 | 5/100 | 7.5/100 | 18/100 | 1.3/100 | 1.3/100 | 513/100 | 100/100 |
| Transferability | | | | | | | |
| Transfer Material 105 | Excellent | Excellent | Excellent | Excellent | Excellent | Poor | Poor |
| Transfer Material 104 | Excellent | Excellent | Excellent | Excellent | Excellent | Poor | Poor |
| Transfer Material 102 | Excellent | Excellent | Excellent | Excellent | Excellent | Poor | Poor |

Note
⁽¹⁾Linear thermal expansion coefficient (ppm/° C.).
⁽²⁾(Rmax of first substrate)/(thickness of transferred organic layer).

As shown in Table 12, the organic EL devices of Examples 39 to 43 were excellent in transferability. In contrast, the organic EL devices of Comparative Examples 9 and 10 exhibited poor transferability, because the ratio of (Rmax of first substrate)/(thickness of transferred organic layer) was more than 50.

### EXAMPLES 44 TO 51

Transfer materials 106 to 108 were prepared in the same manner as in Examples 1 to 8 except for using a quartz glass plate of 5 mm (thickness) ×5 cm×5 cm as a support. The light-emitting organic layers of the transfer materials 106, 107 and 108 were as thick as 15 nm, 40 nm and 80 nm, respectively. Organic EL devices were produced in the same manner as in Examples 1 to 8 except for using each transfer material 106 to 108. The transferability of each organic layer and the laminatability of each organic EL device were evaluated in the same manner as in Examples 1 to 8. The results are shown in Table 13.

### Comparative Examples 11 and 12

Organic EL devices were produced in the same manner as in Comparative Examples 1 and 2 except for using the transfer material 107 as a support. The transferability of each organic layer and the laminatability of each organic EL device were evaluated in the same manner as in Examples 1 to 8. The results are shown in Table 13.

### Reference Example 11

An organic EL device of Reference Example 11 was produced in the same manner as in Reference Example 1 except for using the transfer material 107 as a support. The transferability of the organic layer and the laminatability of the organic EL device were evaluated in the same manner as in Examples 1 to 8. The results are shown in Table 13.

TABLE 13

| | | | | | | |
|---|---|---|---|---|---|---|
| No. | Example 44 | Example 45 | Example 46 | Example 47 | Example 48 | Example 49 |

Transfer Material

| | | | | | | |
|---|---|---|---|---|---|---|
| No. | 106 | 107 | 108 | 107 | 106 | 107 |
| Thickness of Organic | 15 | 40 | 80 | 40 | 15 | 40 |
| Layer (nm) | | | | | | |
| First Substrate | | | | | | |
| No. | 201 | 201 | 201 | 202 | 203 | 203 |
| Rmax (nm) | 2 | 2 | 2 | 3 | 7 | 7 |
| α⁽¹⁾ (ppm/° C.) | 10 | 10 | 10 | 10 | 3 | 3 |
| Structure | UV/PI/Al/PI | UV/PI/Al/PI | UV/PI/Al/PI | TH/PI/Al/PI | Si₃N₄/PI/Al/PI | Si₃N₄/PI/Al/PI |
| Rmax Ratio⁽²⁾ | 13/100 | 5/100 | 3/100 | 8/100 | 47/100 | 18/100 |
| Second Substrate | | | | | | |
| Rmax (nm) | 0.5 | 0.5 | 0.5 | 0.5 | 0.5 | 0.5 |
| α⁽¹⁾ (ppm/° C.) | 4 | 4 | 4 | 4 | 4 | 4 |
| Structure | White Glass | White Glass | White Glass | White Glass | White Glass | White Glass |
| Rmax Ratio⁽³⁾ | 3.3/100 | 13/100 | 0.6/100 | 1.3/100 | 3.3/100 | 1.3/100 |
| Transferability | Excellent | Excellent | Excellent | Excellent | Good | Excellent |
| Laminatability | Excellent | Excellent | Excellent | Excellent | Excellent | Excellent |

| | | | Comparative | Comparative | Reference |
|---|---|---|---|---|---|
| No. | Example 50 | Example 51 | Example 11 | Example 12 | Example 11 |
| Transfer Material | | | | | |
| No. | 107 | 107 | 107 | 107 | 107 |
| Thickness of Organic | 40 | 40 | 40 | 40 | 40 |
| Layer (nm) | | | | | |
| First Substrate | | | | | |
| No. | 204 | 205 | 206 | 207 | 208 |
| Rmax (nm) | 0.5 | 0.5 | 250 | 40 | 3 |
| α⁽¹⁾ (ppm/° C.) | 4 | 0.8 | 10 | 55 | 54 |
| Structure | White Glass | Quartz Glass | PI/Al/PI | PET/Al/PET | UV/PET/Al/PET |
| Rmax Ratio⁽²⁾ | 1.3/100 | 1.3/100 | 625/100 | 100/100 | 7.5/100 |
| Second Substrate | | | | | |
| Rmax (nm) | 0.5 | 0.5 | 0.5 | 0.5 | 0.5 |
| α⁽¹⁾ (ppm/° C.) | 4 | 4 | 4 | 4 | 4 |
| Structure | White Glass | White Glass | White Glass | White Glass | White Glass |
| Rmax Ratio⁽³⁾ | 1.3/100 | 1.3/100 | 3.3/100 | 13/100 | 13/100 |
| Transferability | Excellent | Excellent | Poor | Poor | Excellent |
| Laminatability | Excellent | Excellent | Good | Poor | Good |

Note
⁽¹⁾Linear thermal expansion coefficient (ppm/° C.).
⁽²⁾(Rmax of first substrate)/(thickness of transferred organic layer).
⁽³⁾(Rmax of second substrate)/(thickness of transferred organic layer)

As shown in Table 13, the organic EL devices of Examples 44 to 51 were excellent in transferability and laminatability. In contrast, the organic EL devices of Comparative Examples 11 and 12 exhibited poor transferability and laminatability, because the ratio of (Rmax of first substrate)/(thickness of transferred organic layer) was more than 50. The organic EL device of Reference Example 11 exhibited relatively poor laminatability, because the first substrate had a linear thermal expansion coefficient α of more than 20 ppm/° C.

As described in detail above, an organic layer can be easily formed on a substrate to produce a uniform organic electroluminescent device with a good lamination interface by the method of the present invention using a substrate having a maximum surface roughness Rmax of 0 to 50 according to JIS B 0601-1982, assuming that the organic layer has a thickness of 100.

The organic electroluminescent devices produced by the method of the present invention are useful for full-color display devices, backlights of liquid crystal display devices, illumination surface light sources, light source arrays of printers, etc.

What is claimed is:

1. A method for producing an organic electroluminescent device by using a transfer material comprising at least one organic layer formed on a support, comprising the steps of superposing said transfer material on a first substrate having an electrode formed at least partially thereon such that said organic layer of said transfer material faces said electrode on said first substrate; applying heat and/or pressure thereto to form a laminate; and peeling said support from said laminate so that said organic layer is transferred onto said first substrate via said electrode, wherein said first substrate has a maximum surface roughness Rmax of 0 to 50 according to JIS B 0601-1982, assuming that the thickness of said organic layer is 100.

2. The method of claim 1, wherein after the transfer of said organic layer onto said first substrate via said electrode, a second substrate having an electrode formed at least partially thereon is laminated to said organic layer on said first substrate.

3. The method of claim 2, wherein a surface of said second substrate, on which said electrode is formed, has a maximum surface roughness Rmax of 0 to 50 according to JIS B 0601-1982, assuming that the thickness of said organic layer is 100.

4. The method of claim 2, wherein at least one of said first and second substrates has a linear thermal expansion coefficient of 20 ppm/° C. or less.

5. The method of claim 2, wherein a flat layer is formed on at least one of said first and second substrates.

6. The method of claim 5, wherein said flat layer is made of at least one material selected form the group consisting of ultraviolet-curing organic compounds, electron beam-curing organic compounds, thermosetting organic compounds, inorganic oxides and inorganic nitrides.

7. A method for producing an organic electroluminescent device by using a transfer material comprising at least one organic layer formed on a plate having a pattern, comprising the steps of superposing said transfer material on a first substrate having an electrode formed at least partially thereon such that said organic layer of said transfer material faces said electrode on said first substrate; applying heat and/or pressure thereto to form a laminate; and peeling said plate form said laminate so that said organic layer is transferred onto said first substrate via said electrode, wherein said first substrate has a maximum surface roughness Rmax of 0 to 50 according to JIS B 0601-1982, assuming that the thickness of said organic layer is 100.

8. The method of claim 7, wherein after the transfer of said organic layer onto said first substrate via said electrode, a second substrate having an electrode formed at least partially thereon is laminated to said organic layer on said first substrate.

9. The method of claim 8, wherein a surface of said second substrate, on which said electrode is formed, has a maximum surface roughness Rmax of 0 to 50 according to JIS B 0601-1982, assuming that the thickness of said organic layer is 100.

10. The method of claim 8, wherein at least one of said first and second substrates has a linear thermal expansion coefficient of 20 ppm/° C. or less.

11. The method of claim 8, wherein a flat layer is formed on at least one of said first and second substrates.

12. The method of claim 11, wherein said flat layer is made of at least one material selected form the group consisting of ultraviolet-curing organic compounds, electron beam-curing organic compounds, thermosetting organic compounds, inorganic oxides and inorganic nitrides.

13. An organic electroluminescent device produced by a method comprising the steps of superposing a transfer material comprising at least one organic layer formed on a support on a first substrate having an electrode formed at least partially thereon such that said organic layer of said transfer material faces said electrode on said first substrate; applying heat and/or pressure thereto to form a laminate; and peeling said support from said laminate so that said organic layer is transferred onto said first substrate via said electrode, wherein said first substrate has a maximum surface roughness Rmax of 0 to 50 according to JIS B 0601-1982, assuming that the thickness of said organic layer is 100.

14. The device of claim 13, wherein after the transfer of said organic layer onto said first substrate via said electrode, a second substrate having an electrode formed at least partially thereon is laminated to said organic layer on said first substrate.

15. The device of claim 14, wherein a surface of said second substrate, on which said electrode is formed, has a maximum surface roughness Rmax of 0 to 50 according to JIS B 0601-1982, assuming that the thickness of said organic layer is 100.

16. The device of claim 14, wherein at least one of said first and second substrates has a linear thermal expansion coefficient of 20 ppm/° C. or less.

17. The device of claim 14, wherein a flat layer is formed on at least one of said first and second substrates.

18. The device of claim 17, wherein said flat layer is made of at least one material selected form the group consisting of ultraviolet-curing organic compounds, electron beam-curing organic compounds, thermosetting organic compounds, inorganic oxides and inorganic nitrides.

19. An organic electroluminescent device produced by a method comprising the steps of superposing a transfer material comprising at least one organic layer formed on a plate having a pattern on a first substrate having an electrode formed at least partially thereon such that said organic layer of said transfer material faces said electrode on said first substrate; applying heat and/or pressure thereto to form a laminate; and peeling said plate form said laminate so that said organic layer is transferred onto said first substrate via said electrode, wherein said first substrate has a maximum surface roughness Rmax of 0 to 50 according to JIS B 0601-1982, assuming that the thickness of said organic layer is 100.

20. The device of claim 19, wherein after the transfer of said organic layer onto said first substrate via said electrode, a second substrate having an electrode formed at least partially thereon is laminated to said organic layer on said first substrate.

21. The device of claim 20, wherein a surface of said second substrate, on which said electrode is formed, has a maximum surface roughness Rmax of 0 to 50 according to JIS B 0601-1982, assuming that the thickness of said organic layer is 100.

22. The device of claim 20, wherein at least one of said first and second substrates has a linear thermal expansion coefficient of 20 ppm/° C. or less.

23. The device of claim 20, wherein a flat layer is formed on at least one of said first and second substrates.

24. The device of claim 23, wherein said flat layer is made of at least one material selected form the group consisting of ultraviolet-curing organic compounds, electron beam-curing organic compounds, thermosetting organic compounds, inorganic oxides and inorganic nitrides.
